(19) United States
(12) Patent Application Publication
(10) Pub. No.: US 2007/0223019 A1
(43) Pub. Date: Sep. 27, 2007

(54) Image-forming device

(75) Inventor: Ryuichiro Maeyama, Minamiashigara-shi (JP)

Correspondence Address: MORGAN LEWIS & BOCKIUS LLP, 1111 PENNSYLVANIA AVENUE NW, WASHINGTON, DC, 20004, US

(73) Assignee: Fuji Xerox Co., Ltd.

(21) Appl. No.: 11/603,979

(22) Filed: Nov. 24, 2006

(30) Foreign Application Priority Data
Mar. 22, 2006 (JP) 2006-079767

(51) Int. Cl. G03F 3/08

(52) U.S. Cl. 358/1.9; 358/518

(57) ABSTRACT

An image-forming device has: an image-holding member; a charging unit, an electrostatic latent image forming unit, a toner image forming unit that forms a toner image on the image-holding member using a toner that is in a first state that can form a specific color when color forming information is applied, and is in a second state that cannot form the specific color when non-color forming information is applied, a glossing region selecting unit that selects a glossing region on a recording material, a color forming information applying unit that applies the non-color forming information to a region corresponding to the glossing region, and applies the color forming information to a part of a region not corresponding to the glossing region, a transfer unit, a fixing unit, a color forming unit that forms a color of the toner image.

### BACKGROUND

1. Technical Field

The present invention relates to an image-forming device.

2. Related Art

Image-forming devices using an electrophotographic process are conventionally known. In the image-forming devices using the electrophotographic process, an electrostatic latent image is formed on an image-holding member such as a photoreceptor, developed with a toner to form a visible toner image, and transferred onto a recording material. The toner image transferred onto the recording material is fixed on the recording material by application of heat in a fixing device, and the recording material is discharged sequentially onto, for example, a discharge tray.

In such an image-forming device, the recording media carrying a fixed toner image are stacked on the discharge tray one by one. Here, the recording media immediately after discharge still have heat. For this reason, the piled recording media may adhere to each other, with the resin, which is a component of the toner, undesirably functioning as a binder. In this case, the toner that has fused in the fixing step and has not hardened yet often adheres to another recording material that is in contact with the toner, causing image defects, such as uneven image surface and image peeling, and toner blocking.

### SUMMARY

According to an aspect of the invention, an image-forming device includes: an image-holding member; a charging unit that electrically charges the image-holding member; an electrostatic latent image forming unit that forms an electrostatic latent image on the electrically charged image-holding member, a toner image forming unit that forms a toner image on the image-holding member by adhering a toner on the electrostatic latent image, the toner being in a first state that can form a specific color when color forming information is applied, and the toner being in a second state that cannot form the specific color when non-color forming information is applied, a glossing region selecting unit that selects a glossing region on a recording material that the toner image is to be fixed, a color forming information applying unit that applies the non-color forming information to a region of the toner image that corresponds to the glossing region on the recording material, and applies the color forming information to a part of a region that does not correspond to the glossing region, a transfer unit that transfers the toner image on the image-holding member to the recording material, a fixing unit that fixes the toner image to the recording material, a color forming unit that forms a color of the toner image on the recording material.

### BRIEF DESCRIPTION OF THE DRAWINGS

An exemplary embodiment of the invention will be described in detail based on the following figures, wherein:

FIG. 1 is a schematic view illustrating the configuration of an image-forming device of an exemplary embodiment;

FIG. 2 is a schematic view illustrating the color forming information applying unit of the image-forming device of FIG. 1;

FIG. 3 is a block diagram of a part of the image-forming device of FIG. 1;

FIG. 4 is a block diagram showing a picture region/character region judgment unit;

FIG. 5 is a flowchart showing processes executed by a controller;

FIGS. 6A to 6E are schematic views illustrating an image-forming process in the image-forming device of FIG. 1; FIG. 6A shows an image formed on a recording material; FIG. 6B shows an electrostatic latent image formed on a photoreceptor; FIG. 6C shows a toner image formed on the photoreceptor; FIG. 6D shows the toner image formed on the photoreceptor after application of color forming information; and FIG. 6E shows the image formed on a recording material;

FIG. 7 is a view illustrating a glossy image formed on a recording material by the image-forming device of FIG. 1; and

FIGS. 8A and 8B are views illustrating the color-forming mechanism of a toner; FIG. 8A shows the color-forming portion; and FIG. 8B is an enlarged view thereof

### DETAILED DESCRIPTION

Hereinafter, the invention will be described in detail.

The image-forming device has: an image-holding member; a charging unit that electrically charges the image-holding member; an electrostatic latent image forming unit that forms an electrostatic latent image on the electrically charged image-holding member, a toner image forming unit that forms a toner image on the image-holding member by adhering a toner on the electrostatic latent image, the toner being in a first state that can form a specific color when color forming information is applied, and the toner being in a second state that cannot form the specific color when non-color forming information is applied, a glossing region selecting unit that selects a glossing region on a recording material that the toner image is to be fixed, a color forming information applying unit that applies the non-color forming information to a region of the toner image that corresponds to the glossing region on the recording material, and applies the color forming information to a part of a region that does not correspond to the glossing region, a transfer unit that transfers the toner image on the image-holding member to the recording material, a fixing unit that fixes the toner image to the recording material, a color forming unit that forms a color of the toner image on the recording material.

In the image-forming device of the invention, a toner that can switch from a first state that can form a specific color (a color-forming state) to a second state that cannot form the specific color (a non-color-forming state) or vice versa. When color forming information has been applied to the toner by, for example, irradiating light having a specific wavelength, the toner is in the first state. When non-color forming information has been applied to the toner, the toner is in the second state. As a result, a specific color can be formed or cannot be formed in the applied region.

An image-holding member is electrically charged to a particular electrostatic potential by a charging unit and is then exposed to light by an electrostatic latent image forming unit. At this time, the electrostatic latent image forming unit irradiates the electrically charged image-holding member with light modulated so as to form an electrostatic latent image on the image-holding member. The detail of the light exposure will be explained later. A toner image forming unit contains the toner therein and adheres the toner to the image-holding member so as to form, on the image-holding member, a toner image corresponding to the electrostatic latent image.

A color forming information-applying unit applies the non-color forming information to a region of the toner image that corresponds to a glossing region, which will be described later, on a recording material and applies the color forming information to a part of a region of the toner image that does not correspond to the glossing region

Before or after the application of the non-color forming information and color forming information, the toner image is then transferred to a recording material by a transfer unit. Thereafter, the applied toner image is fixed on the recording material by a fixing unit. A color forming unit forms the color of the toner image on the recording material. In other words, the color forming unit causes the part of a region of the toner image that does not correspond to the glossing region to from the specific color. As a result, the specific color is formed in a region of the toner image which region corresponds to, for example, the image of an original and the specific color is not formed in the glossing region. When the image of an original has plural colors, the plural colors are formed in the region of the toner image which region corresponds to the image of an original, and the plural colors are not formed in the glossing region. Here, the toner in the glossing region has underwent, for example, a stimulus such as heat and thereby has been glossed.

A glossing region-selecting unit selects the glossing region on the recording material.

As described above, the image-forming device of the invention allows glossing the glossing region that is selected by the glossing region-selecting unit without additionally providing a complicated device such as a cooling device. Regardless of capability of selectively glossing a desired region of a recording material, the image-forming device has a simple configuration.

The image-forming device may further have an image data acquiring unit that acquires image data according to the image of an original, a glossing region data forming unit that forms data of the glossing region based on the selected glossing region, a composite image data forming unit that integrates the image data and the data of the glossing region to form a composite image data. In this case, the electrostatic latent image forming unit forms an electrostatic latent image by irradiating the image-holding member based on the composite image data.

The image data includes at least one of picture regions and character regions, and the glossing region electing unit selects the glossing region on the basis of a picture region.

The glossing region selecting unit selects, for example, a region touching and surrounding the picture region as the glossing region. Thus, the periphery of a character region is not glossed, which does not damage visibility of the character region.

Thus, a desired region can be selectively glossed.

The picture region may be a graphic or a photograph.

The image-forming device may further include an image-type information acquiring unit that acquires image-type information indicating a type of image included in the toner image. In this case, the glossing region selecting unit selects a region touching and surrounding the region that corresponds to the image type of the acquired image-type information as the glossing region.

One unit may serve as both of the color forming unit and the fixing unit. The toner used in the image-forming device of the invention is preferably heated to form the specific color. Accordingly, integration of the color forming unit and the fixing unit enables use of heat in order to fix and form the specific color. In this case, it becomes possible to efficiently use energy, reducing the size of the image-forming device.

The image-forming device of the invention may further include a post-fixing irradiating unit that irradiates the toner image after the toner image is fixed on the recording material.

Specific color forming reaction may continue in the toner after the specific color is formed in the toner image on the recording material. The post-fixing irradiation makes it possible to inactivate reactive substances associated with the specific color forming reaction and remaining in the region where the specific color has been formed, securing prevention of fluctuation in color balance after image formation, and eliminating or whitening a background color.

The toner used in the invention may have a first component and a second component that are present separated from each other and form a color when reacted with each other and a photocurable composition containing any one of the first component and the second component, and, by applying the color forming information and the non-color forming information with light, the photocurable composition holds a cured or uncured state to control the reaction for color forming.

In the invention, a region of the toner image which region corresponds to the glossing region selected by the glossing region selecting unit may have the inherent color of the toner, after the color forming. For example, when an irradiated portion of the toner image forms a color by heating, the color forming information applying unit irradiates all the portion of the toner image but the glossing region. Alternatively, when a non-irradiated portion of the toner image forms a color by heating, the color forming information applying unit irradiates only the glossing region. More specifically, when the toner includes three combinations of color-forming components that respectively form, for example, yellow, magenta and cyan colors, and an irradiated portion of the toner image forms a color by heating, the color forming information applying unit irradiates some portions of the toner image that do not include the glossing region with light having a wavelength necessary to form a yellow color, irradiates some portions of the toner image that do not include the glossing region with light having a wavelength necessary to form a magenta color, and irradiates some portions of the toner image that do not include the glossing region with light having a wavelength necessary to form a cyan color. Alternatively, when the toner includes three combinations of color-forming components that respectively form, for example, yellow, magenta and cyan colors, and a non-irradiated portion of the toner image forms a color by heating, the color forming information applying unit irradiates some portions of the toner image that include the glossing region with light having a wavelength necessary to inhibit formation of a yellow color, irradiates some portions of the toner image that include the glossing region with light having a wavelength necessary to inhibit formation of a magenta color, and irradiates some portions of the toner image that include the glossing region with light having a wavelength necessary to inhibit formation of a cyan color.

When the toner image is transferred onto a recording material, and fixed thereon and the specific color is partially formed in the toner image, an image that corresponds to the image data and that may be a full-color image is formed on the recording material, and the toner fixed on the glossing region selected by the glossing region selecting unit does not form a color or colors but may have the inherent color of the toner. The toner may include one or more combinations of color-forming components.

For example, when irradiated with light of different wavelengths, each of the toner particles for use in the invention has a function of switching from a first state where a specific color can be formed and a second state where the specific color cannot be formed. Such a toner contains therein at least one color-forming substance that forms the specific color when the toner is in the first state and, for example, undergoes a specific stimulus other than light (and further includes a color-forming portion containing the at least one color-forming substance). When the toner image is irradiated with light in this case, the toner is changed from the first state to the second state or vice versa.

The phrase “the toner image is irradiated with light” means that individual toner particles in a desired region of a toner image are selectively exposed to light having one or more wavelengths or are not exposed to the light so as to switch the individual toner particles from the first state to the second state or vice versa and to control color tone to be formed.

When the toner image is irradiated with light having at least one specific wavelength, each of the toner particles of the toner image changes from a first state where a color or colors corresponding to the wavelength(s) of the irradiated light can be formed to a second state where the color or colors cannot be formed or vice versa.

The toner may contain, as color-forming substances, at least two kinds of reactive components (hereinafter, referred to as first and second components) that react with each other to form a color and a color-forming portion containing the color-forming substances, and switches from the first state to the second state or vice versa by applying color forming information and non color forming information to the toner image and forms a color by heating the toner image to which the color forming information and the non color forming information have been applied. The detail of the color-forming portion will be described later.

The first and second components are contained in separate matrices where, unless the toner is in the first state and, for example, heated, diffusion of a substance or substances contained in one of the separate matrices into the other is hindered. In other words, these components are isolated from each other.

Specifically, the first component of the two kinds of reactive components is contained in a first matrix, and the second component is contained in another matrix (second matrix). It is preferable to dispose a barrier layer having functions of ordinarily prohibiting diffusion of substances between the first and second matrices and of, when for example, an external stimulus or stimuli such as heat is applied thereto, allowing diffusion of the substances between the matrices according to the kind(s) and the strength(s) of the stimulus or stimuli, and the combination of the stimuli.

Microcapsules are preferably used as such a barrier layer to place the two kinds of reactive components in the toner in an isolated state. The first or second component of the two kinds of reactive components of the toner is preferably contained in the microcapsules and the other is disposed outside the microcapsules.

When the first component is contained in the microcapsules and the second component is disposed outside the microcapsules, the regions in the microcapsules are the first matrix and the region outside the microcapsules is the second matrix.

Each of the microcapsules has a core and a shell covering the core. The microcapsules have a function of prohibiting diffusion of, unless, for example, an external stimulus or stimuli such as heat is applied to the microcapsules, substances between the inside and the outside thereof and, when an external stimulus or stimuli is applied, allowing diffusion of the substances between the inside and the outside thereof according to the kind(s) and the strength(s) of the stimulus or stimuli, and the combination of the stimuli. At least one of the reactive components is contained in the cores. There is not any other limit to the microcapsules.

The microcapsules may allow diffusion of substances between the inside and the outside thereof by, for example, application of at least one stimulus such as light or pressure. However, the microcapsules are preferably heat-responsive microcapsules that, when heated, allows diffusion of substances between the inside and the outside thereof (and specifically, having shells whose ability of allowing substances to permeate the shells increases by heating).

The diffusion of substances between the inside and the outside of the microcapsules by, for example, applying at least one stimulus to the microcapsules is preferably irreversible so as to prevent deterioration in the color density of an image formed and change in color balance of the image which change is caused by leaving the image under a high-temperature environment.

Accordingly, the shells of the microcapsules preferably have a function of, for example, softening, decomposing, being solubilized (being compatibilized with a surrounding material), or deforming during, for example, application of at least one stimulus such as heat or light irradiation to irreversibly increase its ability of allowing a substance or substances to permeate the shells.

The toner for use in the invention has the aforementioned functions, and otherwise there is no particular limit thereto. The toner may be a toner described in JP-A No. H04-104264 or H10-90965, but is preferably the following toner to allow many microcapsules to exist in the toner without localization of the microcapsules in the toner.

As described previously, a toner containing a first component and a second component that are present separated from each other and form a color when reacted with each other and a photocurable composition containing any one of the first component and the second component, and, by applying the color forming information or the non-color forming information with light, the photocurable composition holds a cured or uncured state to control the reaction for color forming (hereinafter, referred to as an “F toner”) can be used in the invention as the toner that can switch from the first state to the second state or vice versa.

First, the mechanism of color forming of the F toner for use in the invention will be described.

The toner usable in the invention may have, in a binder resin, one or more continuous regions that are called color-forming portions, and that, when non-color forming information is applied to a toner image, switch from a first state where a specific color can be formed (color-forming state) to a second state where the specific color cannot be formed (i.e., non-color-forming state) or, when color forming information is applied to the toner image, switch from the second state to the first state, as will be described later in detail. Here, application of color forming information or non-color forming information may be non-irradiation of light.

When the toner particles include plural color-forming regions that can form different colors, the plural color-forming regions are isolated from each other, so that the materials contained in the respective regions are not mixed.

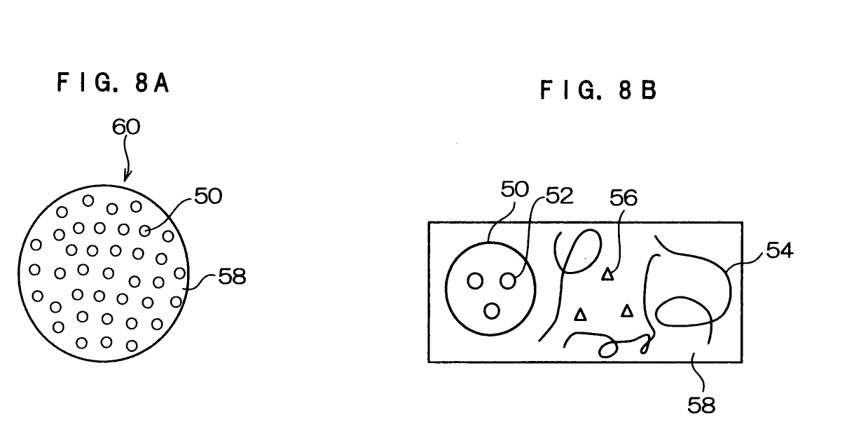

As described above, the toner particles in the invention have, as at least one continuous region each of which can form a color and switch from a color-forming state (first state) to a non-color-forming state (second state) or vice versa, one or more color-forming portions. When the toner particles have two or more continuous regions, the continuous regions can form different colors. As shown in FIG. 8A, each color-forming portion 60 contains microcapsules 50 containing a color-forming agent and a photocurable composition 58 surrounding the microcapsules. In other words, the microcapsules 50 are dispersed in the photocurable composition 58 in the color-forming portion 60.

As shown in FIG. 8B, which is an enlarged view illustrating a part of the color-forming portion 60, the color-forming portion 60 contains microcapsules 50, a color-forming agent (first component) 52, a developer monomer (second component) 54 that has at least one polymerizable functional group and that, when disposed in the vicinity of the color-forming agent 52 or brought into contact with the color-forming agent 52, causes the color-forming agent 52 to form a color, and a photopolymerization initiator 56.

Each of the microcapsules 50 contains the color-forming agent (first component) 52 therein. The photocurable composition 58 surrounding the microcapsules 50 contains the developer monomer (second component) 54 that has at least one polymerizable functional group and that, when disposed in the vicinity of the color-forming agent 52 or brought into contact with the color-forming agent 52, causes the color-forming agent 52 to form a color, and the photopolymerization initiator 56.

The color-forming agent (first component) 52 is preferably a triaryl leuco compound, which has excellent vividness of color tone.

The developer monomer 54 that causes the color-forming agent 52 such as a leuco compound (electron-donating compound) to form a color is preferably an electron-accepting compound. The developer monomer 54 is generally a phenol compound and may be selected properly from developers used in, for example, thermosensitive and pressure-sensitive paper.

The electron-donating compound serving as the color-forming agent 52 and the electron-accepting compound serving as the developer monomer 54 react with each other to conduct acid-base reaction, causing the color-forming agent 52 to form a color.

The photopolymerization initiator 56 is a spectral sensitizing dye that is sensitive to visible light and that generates at least one polymerizable radical, which triggers polymerization of the developer monomer 54.

The photocurable composition 58 may further contain at least one accelerator that accelerates reaction of the photopolymerization initiator 56 to sufficiently accelerate polymerization reaction of the developer monomer 54 during irradiation of light, for example, having three primary colors of red (R), green (G), and blue (B). For example, when an ion complex including a spectral sensitizing dye (cation) that absorbs irradiated light and a boron compound (anion) is used, the spectral sensitizing dye is excited by light irradiation to generate electrons, and the electrons are transferred to the boron compound so as to generate polymerizable radicals, which initiate polymerization of the developer monomer.

A photosensitive color-forming portion 60 containing a combination of those materials may have a color forming recording sensitivity of approximately 0.1 to 0.2 mJ/cm².

When a toner image is partially irradiated to apply color forming information and non-color forming information thereto, a part or all of color-forming portions 60 contained in the toner particles are irradiated. Color-forming portions 60 that have been irradiated contain a product obtained by polymerizing the developer monomer 54. Meanwhile, color-forming regions 60 that have not been irradiated contain the developer monomer 54 itself

After or before the color forming information and the non-color forming information have been applied, the toner image is transferred to a recording material. Thereafter, the toner image to which the color forming information and the non-color forming information have been applied is fixed on the recording material. During or after the fixation, the toner image is heated. During the heating, the developer monomer 54 in the color-forming portions 60 to which the color forming information has been applied migrates, passes through the pores of the shells of the microcapsules 50, and diffuses into the cores of the microcapsules. The developer monomer 54 that has diff-used into the cores of the microcapsules 50 and that is acidic reacts with the color-forming agent 52 that is contained in the microcapsules 50 and that is basic to cause the color-forming agent 52 to form a color, as described previously.

On the other hand, the product that is obtained by polymerizing the developer monomer 54 and that is bulky cannot pass through the pores of the shells of the microcapsules 50 and cannot diffuse into the cores of the microcapsules even when the toner image is heated. As a result, the product cannot react with the color-forming agent 52 contained in the microcapsules 50 and a color cannot be formed. Accordingly, the components in the microcapsules 50 have their inherent color. In short, the color-forming portions 60 irradiated with light having a particular wavelength have their inherent color(s), which may be colorless.

When the entire surface of the recording material is exposed to white light after the color forming, all residual developer monomer molecules 54 are polymerized to firmly fix the developed image on the recording material and residual spectral sensitizing dye molecules are also decomposed to decolorize the background portion on the recording material. When the spectral sensitizing dye serving as a photopolymerization initiator 56 is sensitive to visible light, the color tone thereof remains as the background color. For decoloration of such a spectral sensitizing dye, an optical decoloration phenomenon between the spectral sensitizing dye and a boron compound may be used. Specifically, when the spectral sensitizing dye is optically excited, the generated electrons are transferred from the excited dye to the boron compound to generate polymerizable radicals, which not only initiate polymerization of the developer monomer but also react with the excited dye radical to decompose the color of the dye and consequently decolorize the dye.

The F toner may have color-forming portions 60 that form different colors (for example, yellow (Y), magenta (M), and cyan (C) colors). Each of the color-forming portions 60 may include a developer monomer 54 and may have microcapsules where a color-forming agent 52 suitable for the developer monomer 54 is so contained therein as to isolate the color-forming agent 52 from the developer monomer 54. When the toner has plural color-forming portions containing respective color-forming agents 52 that can form different colors, the plural color-forming portions are so provided as to isolate respective content materials from each other and as to prevent mixing of the content materials.

The remaining space of each of the color-forming portions of the toner other than the microcapsules 50 containing the electron-donating compound as the color-forming agent 52 is filled with the photocurable composition 58 including the electron-accepting compound as the developer monomer 54. Since such a color-forming portion 60 is irradiated with light, the light-receiving efficiency of each of the toner particles is drastically higher than that of the toner disclosed in JP-A No. H10-90965.

Further, the changing mechanism of the toner image by application of color forming information and non-color forming information is not a reversible reaction, as described previously. Therefore, there is no limit to a time starting at color forming information and non-color forming information application and ending at color forming due to heating in the image-forming device. As a result, it is possible to form an image at any of low, middle, and high speeds. In other words, the image-forming device can adapt to a wide speed range. In addition, the image-forming device has a high degree of freedom with respect to positions at which a fixing unit and a color forming unit utilizing heat are disposed.

The F toner for use in the invention will be described below in more detail.

Examples of the F toner for use in the invention include the following three embodiments.

An F toner of a first embodiment contains first and second components that react with each other to form a color, a photocurable composition, and microcapsules dispersed in the photocurable composition, wherein the first component is contained in the microcapsules and the second component is contained in the photocurable composition. An F toner of a second embodiment contains first and second components that react with each other to form a color, and microcapsules containing a photocurable composition, wherein the first component is contained out the microcapsules and the second component is contained in the photocurable composition. An F toner of a third embodiment contains first and second components that react with each other to form a color, microcapsules containing the first component, and other microcapsules containing a photocurable composition where the second component is dispersed.

Among the three embodiments, the toner of the first embodiment is preferably used from the viewpoints of stability thereof before color forming information and non-color forming information application, due to light and good controllability of color forming. The following detailed descriptions are mainly applied to the toner of the first embodiment, but the configuration, the materials, and the production method of the toner of the first embodiment may also be applied to the toners of the second and third embodiments.

The F toner containing a combination of thermosensitive microcapsules and a photocurable composition is preferably one of the following two toners.

(1) A toner including a photocurable composition that contains a second component, wherein, when the photocurable composition that has not been cured is heated, diffusion of the second component is suppressed, and, when the photocurable composition that has been cured by light irradiation for color forming information application is heated, diffusion of the second component contained therein is accelerated (hereinafter, referred to as an “optical color-forming toner” in some cases)

(2) A toner including a photocurable composition that contains a second component, wherein, when the photocurable composition that has not been cured and in which the second component has not been polymerized is heated, diffusion of the second component is accelerated, and, when the photocurable composition that has been cured by light irradiation for non-color forming information application and in which the second component has been polymerized is heated, diffusion of the second component contained therein is suppressed (hereinafter, referred to as a “non-optical color-forming toner” in some cases).

The major difference between the optical color-forming toner and the non-optical color-forming toner is the material(s) of the photocurable composition. Specifically, the photocurable composition of the optical color-forming toner contains a non-photopolymerizable second component and at least one photopolymerizable compound, while the photocurable composition of the non-optical color-forming toner contains a second component having at least one photopolymerizable group in the molecule thereof

The photocurable compositions contained in the optical color-forming toner and the non-optical color-forming toner preferably contain at least one photopolymerization initiator and may further contain other materials, if necessary.

The photopolymerizable compound and the second component used in the photocurable composition of the optical color-forming toner are materials that, when the photocurable composition has not been cured, interact with each other to suppress diffusion of the second component in the photocurable composition, and, when the photocurable composition has been cured by light irradiation for color forming information application, or, in other words, when the photopolymerizable compound has been polymerized, less interact with each other, facilitating diffusion of the second component in the photocurable composition.

Accordingly, diffusion of the second component contained in the photocurable composition of the optical color-forming toner becomes easy by irradiating the toner with light having a wavelength that can cure the photocurable composition in applying the color forming information before the specific color in the toner is formed by heating. When the toner image is then heated to, for example, melt the shells of the microcapsules, the first component in the microcapsules and the second component in the photocurable composition react with each other to form a color.

On the contrary, when the photocurable composition is not irradiated with light having a wavelength that can cure the photocurable composition in applying the non-color forming information but is heated, the second component is trapped in the photopolymerizable compound and cannot come into contact with the first component in the microcapsules, prohibiting reaction between the first and second components and color forming.

As described above, reaction between the first and second components of the optical color-forming toner to form a color can be controlled by combining non-irradiation or irradiation of light having a wavelength within a specified wavelength region that can cure the photocurable composition in applying the color forming information and the non-color forming information and heating the toner image.

Meanwhile, the second component itself of the non-optical color-forming toner is photopolymerizable. When the photocurable composition is not irradiated with light having a wavelength that can cure the photocurable composition in applying the color forming information, diffusion of the second component contained in the photocurable composition is easy. Therefore, when the photocurable composition that has not been irradiated with the light is heated to, for example, melt the shells of the microcapsules, the first component in the microcapsules and the second component in the photocurable composition react with each other to form a color.

In contrast, when the photocurable composition is irradiated with light having a wavelength that can cure the photocurable composition before heating, the second component contained in the photocurable composition is polymerized, making diffusion of the second component difficult. Therefore, even if the toner image is then heated, the second component cannot come into contact with the first component in the microcapsules, prohibiting reaction between the first and second components and color forming.

As described above, reaction between the first and second components of the non-optical color-forming toner to form a color can be controlled by combining non-irradiation or irradiation of light having a wavelength within a specified wavelength region that can cure the photocurable composition in applying the color forming information and the non-color forming information, and heating the toner image.

In the following, an F toner that contains a photocurable composition and microcapsules dispersed in the photocurable composition, which is a preferred configuration of an F toner, will be described in more detail.

In this case, the toner may contain only one color-forming portion containing a photocurable composition and microcapsules dispersed in the photocurable composition, but preferably contains two or more color-forming portions.

As described previously, the “color-forming portion” means a continuous region capable of forming a specific color when, for example, an external stimulus or stimuli are applied thereto.

When the toner contains two or more color-forming portions, the color-forming portions may form the same color. However, the color-forming portions preferably form different colors. This is because the number of colors that one toner particle can form is only one in the former case but is two or more in the latter case.

For example, the two or more color-forming portions may be those that form yellow, magenta, and cyan colors, respectively.

When only one of the color-forming portions in each toner particle forms a color by application of an external stimulus or stimuli in this case, the color is yellow, magenta, or cyan. When two color-forming portions in each toner particle form the respective colors, the toner can form a color obtained by combining the colors formed by the two color-forming portions. In this way, each toner particle may form various colors.

The color formed by the toner containing two or more color-forming portions that form different colors can be controlled by selecting the kinds and the combination of the first and second components contained in each kind of color-forming portion and by using light having different wavelengths to cure the respective photocurable compositions contained in the two or more color-forming portions.

Because the wavelength of light necessary to cure the photocurable composition contained in a color-forming region depends on the kind of the photocurable composition in this case, light of different wavelengths is used to apply color forming information or non-color forming information to a toner image according to the kinds of the photocurable compositions of the color-forming portions.

To use light of different wavelengths so as to cure the respective photocurable compositions contained in the color-forming portions, the photocurable compositions preferably contain photopolymerization initiators sensitive to light of different wavelengths suitable for the respective compositions.

When each toner particle contains three color-forming portions that respectively form yellow, magenta, and cyan colors and that include respective photocurable compositions, these photocurable compositions may be most effectively cured by respectively irradiating them with light of wavelengths of, for example, 405 nm, 532 nm and 657 nm at the same light exposure. In this case, the toner may form a desired color by selecting the wavelength(s) of light irradiated to cure desired photocurable composition(s). The wavelength(s) of the light used to irradiate the toner may be within the visible or ultraviolet range.

The toner for use in the invention may contain a base material including, as the main component thereof, a binder resin, as in conventional toners including a colorant such as a pigment. In this case, each of two or more color-forming portions is preferably dispersed in the base material as a particulate capsule (hereinafter, such a capsular color-forming portion is referred to as a “photosensitive and thermosensitive capsule” in some cases). At least one releasing agent and/or any other additive(s) may also be contained in the base material, as in the conventional toners containing a colorant such as a pigment.

Each of the photosensitive and thermosensitive capsules has a core containing microcapsules and a photocurable composition, and a shell encapsulating the core. The shell needs to stably contain the microcapsules and the photocurable composition therein without leakage of the microcapsules and the photocurable composition therefrom during a toner production process described later and during storage of the toner, and otherwise there is no particular limit to the shell.

In the invention, the photosensitive and thermosensitive capsules preferably contain, as the main component thereof, a binder resin that is water-insoluble, or a water-insoluble substance such as a releasing agent to prevent the second component that can form a color and that is contained in the capsules (primary capsules) from permeating the shells of the capsules into a matrix out of the capsules, and to prevent a second component that can form another color and that is contained in secondary capsules from permeating the shells of the secondary and primary capsules into the inside of the primary capsules in a toner production process described later.

Next, the components of the F toner, a method of preparing each of the components and materials used in the method will be described in more detail.

In the invention, the toner may contain microcapsules containing a first component, and a photocurable composition containing a second component. The photocurable composition preferably contains at least one photopolymerization initiator, and may contain various assistants. The first component in the microcapsules (cores) may be solid or be dissolved in a solvent.

In the non-optical color-forming toner, an electron-donating colorless dye or diazonium salt compound is used as the first component, and a photopolymerizable group-containing electron-accepting compound or a photopolymerizable group-containing coupler compound is used as the second component. Meanwhile, in the optical color-forming toner, an electron-donating colorless dye is used as the first component, and an electron-accepting compound (hereinafter, referred to as an “electron-accepting developer” or a “developer” in some cases) is used as the second component, and a polymerizable compound having an ethylenic unsaturated bond is used as a photopolymerizable compound.

In addition to these materials, various materials similar to the materials of conventional toners including a colorant, such as a binder resin, a releasing agent, an internal additive, and an external additive, may be used to prepare the toner, if necessary. Hereinafter, each of the materials will be described in more detail.

### —First and Second Components—

Examples of a combination of the first and second components include the following combinations (a) to (r) (in the following examples, the first compound is the first component and the second compound is the second component).

(a) Combination of an electron-donating colorless dye and an electron-accepting compound

(b) Combination of a diazonium salt compound and a coupling component (hereinafter, referred to as a “coupler compound”)

(c) Combination of a metal salt of an organic acid such as silver behenate or silver stearate, and a reducing agent such as protocatechin acid, spiroindane, or hydroquinone

(d) Combination of an iron salt of a long-chain fatty acid such as ferric stearate or ferric myristate, and a phenol compound such as tannic acid, gallic acid, or ammonium salicylate

(e) Combination of a heavy metal salt of an organic acid such as nickel, cobalt, lead, copper, iron, mercury, or silver salt of acetic acid, stearic acid, or palmitic acid, and an alkali metal sulfide or an alkaline earth metal sulfide such as calcium sulfide, strontium sulfide, or potassium sulfide, or combination of the heavy metal salt of an organic acid and an organic chelating agent such as s-diphenylcarbazide or diphenylcarbazone

(f) Combination of a heavy metal sulfate such as silver sulfate, lead sulfate, mercury sulfate, or sodium sulfate, and a sulfur compound such as sodium tetrathionate, sodium thiosulfate, or thiourea

(g) Combination of an aliphatic ferric salt such as ferric stearate, and an aromatic polyhydroxy compound such as 3,4-hydroxytetraphenylmethane

(h) Combination of a metal salt of an organic acid such as silver oxalate or mercury oxalate, and an organic polyhydroxy compound such as polyhydroxyalcohol, glycerol, or glycol

(i) Combination of a ferric salt of a fatty acid such as ferric pelargonate or ferric laurate, and a thiocesylcarbamide or isothiocesylcarbamide derivative

(j) Combination of a lead salt of an organic acid such as lead caproate, lead pelargonate, or lead behenate, and a thiourea derivative such as ethylenethiourea or N-dodecylthiourea

(k) Combination of a heavy metal salt of a higher fatty acid such as ferric stearate or copper stearate, and zinc dialkyldithiocarbamate

(l) Combination of compounds that produce an oxazine dye such as a combination of resorcin and a nitroso compound

(m) Combination of a formazan compound and a reducing agent and/or a metal salt

(n) Combination of a protected dye (or leuco dye) precursor and a deprotecting agent

(o) Combination of an oxidative color-forming agent and an oxidizing agent

(p) Combination of a phthalonitrile compound and a diiminoisoindoline compound (combination of compounds that produce phthalocyanine)

(q) Combination of an isocyanate compound and a diiminoisoindoline compound (combination of compounds that produce a color-forming pigment)

(r) Combination of a pigment precursor and an acid or a base (combination of compounds that produce a pigment)

The first component is preferably an electron-donating colorless dye or a diazonium salt compound that is substantially colorless.

Any one of known electron-donating dyes that can react with the second component to form a color may be used as the electron-donating colorless dye. Specific examples thereof include phthalide compounds, fluorane compounds, phenothiazine compounds, indolylphthalide compounds, leucoauramine compounds, rhodamine lactam compounds, triphenylmethane compounds, triazene compounds, spiropyran compounds, pyridines, pyrazine compounds, and fluorene compounds.

The second component of the non-optical color-forming toner may be any of substantially colorless compounds that have, in one molecule, a photopolymerizable group and a site that reacts with the first component to form a color and that have functions of reacting with the first component, such as a photopolymerizable group-containing electron-accepting compound or a photopolymerizable group-containing coupler compound, to form a color, and of, when exposed to light, polymerizing and curing.

Any of compounds that have at least one photopolymerizable group and that react with an electron-donating colorless dye serving as the first component to form a color and that, when exposed to light, are polymerized and cured may be used as the photopolymerizable group-containing electron-accepting compound, i.e., a compound having an electron-accepting group and at least one photopolymerizable group in one molecule.

Examples of the electron-accepting developer serving as the second component of the optical color-forming toner include phenol derivatives, sulfur-containing phenol derivatives, organic carboxylic acid derivatives (such as salicylic acid, stearic acid, and resorcylic acid) and metal salts thereof, sulfonic acid derivatives, urea and thiourea derivatives, acid clay, bentonite, novolak resins, novolak resins treated with metals, and metal complexes.

In addition, the optical color-forming toner contains, as a photopolymerizable compound, a polymerizable compound having at least one ethylenic unsaturated bond. Examples thereof include acrylic acid and salts thereof, acrylic esters, and acrylamides.

Hereinafter, a photopolymerization initiator will be described. When irradiated with light used to apply color forming information to a toner image, the photopolymerization initiator generates radicals, which initiate and accelerate polymerization reaction in the photocurable composition. The photocurable composition cures in the polymerization reaction.

The photopolymerization initiator may be properly selected from known photopolymerization initiators. The photopolymerization initiator is preferably a combination of at least one spectral sensitizing compound having a maximum absorption wavelength within the range of about 300 nm to about 1,000 nm, and at least one compound that interacts with the spectral sensitizing compound.

Alternatively, the photopolymerization initiator is a compound that has both a dye site having a maximum absorption wavelength within the range of about 300 nm to about 1,000 nm and a borate site in the structure thereof.

Each of the at least one compound that interacts with the spectral sensitizing compound may be properly selected from known compounds that initiate photopolymerization reaction of the photopolymerizable group contained in the second component.

Co-presence of such a compound with the spectral sensitizing compound can form a photopolymerization initiator that is highly sensitive to irradiated light having a wavelength within the spectral absorption wavelength region so as to efficiently generate radicals, and that allows control of radical generation by using any of light sources emitting light within the ultraviolet and infrared regions.

The “compound that interacts with a spectral sensitizing compound” is preferably an organic borate salt compound, benzoin ether, an S-triazine derivative with a substituted methyl group having three halogen atom substituents, an organic peroxide, or an azinium salt compound, and more preferably an organic borate salt compound. Combined use of the “compound that interacts with a spectral sensitizing compound” with the spectral sensitizing compound makes it possible to locally and effectively generate radicals in the irradiated region of a toner image and to provide a photopolymerization initiator having an improved sensitivity.

A reducing agent such as an oxygen scavenger or an active hydrogen donor chain-transfer agent, and other compounds that accelerate polymerization in a chain reaction manner may be contained in the photocurable composition as assistants for accelerating polymerization reaction.

The oxygen scavenger may be phosphine, phosphonate, phosphite, a primary silver salt, or other compound that may be easily oxidized with oxygen. Specific examples thereof include N-phenylglycine, trimethylbarbituric acid, N,N-dimethyl-2,6-diisopropylaniline, and N,N,N-2,4,6-pentamethylanilinic acid. In addition, thiols, thioketones, trihalomethyl compounds, Rofin dimer compounds, iodonium salts, sulfonium salts, azinium salts, organic peroxides, and azides are useful as polymerization accelerators.

The first component such as an electron-donating colorless dye or a diazonium salt compound is encapsulated in microcapsules in the F toner.

A microcapsulation method may be any known method. Examples thereof include methods using coacervation of a hydrophilic wall-forming material described in U.S. Pat. Nos. 2,800,457 and 2,800,458; interfacial polymerization methods described in U.S. Pat. No. 3,287,154, British Patent No. 990,443, and Japanese Patent Application Publication (JP-B) Nos. S38-19574, S42-446, and S42-771; polymer precipitation methods described in U.S. Pat. Nos. 3,418,250 and 3,660,304; a method using an isocyanate-polyol wall material described in U.S. Pat. No. 3,796,669; a method using an isocyanate wall material described in U.S. Pat. No. 3,914,511; methods using a urea-formaldehyde wall-forming material or a urea formaldehyde-resorcinol wall-forming material described in U.S. Pat. Nos. 4,001,140, 4,087,376, and 4,089,802; a method using a wall-forming material such as a melamine-formaldehyde resin or hydroxypropylcellulose described in U.S. Pat. No. 4,025,455; in-situ methods due to monomer polymerization described in JP-B No. S36-9168 and JP-A No. S51-9079; electrolytic dispersion cooling methods described in British Patent Nos. 952807 and 965074; spray drying methods described in U.S. Pat. No. 3,111,407 and British Patent No. 930,422; and methods described in JP-B No. H07-73069, and JP-A Nos. H04-101885 and H09-263057.

The material(s) of the microcapsule walls is added to the inside and/or outside of oil droplets. Examples of the material of the microcapsule walls include polyurethane, polyurea, polyamide, polyester, polycarbonate, urea-formaldehyde resins, melamine resins, polystyrene, styrene-methacrylate copolymers, and styrene-acrylate copolymers. Among them, the material(s) is preferably polyurethane, polyurea, polyamide, polyester, and/or polycarbonate, and more preferably polyurethane and/or polyurea. Two or more of those polymers may be used as the materials of the microcapsule walls.

The volume-average particle diameter of the microcapsules is preferably in the range of about 0.1 to about 3.0 μm, and more preferably in the range of about 0.3 to about 1.0 μm.

The photosensitive and thermosensitive capsules may contain a binder. This is applicable to the case of a toner having one color-forming portion.

Examples of the binder include binders similar to those used in emulsification and dispersion of the photocurable composition; water-soluble polymers used in encapsulation of the first reactive substance; solvent-soluble polymers such as polystyrene, polyvinyl formal, polyvinyl butyral, acrylic resins including polymethyl acrylate, polybutyl acrylate, polymethyl methacrylate, polybutyl methacrylate and copolymers thereof, phenol resins, styrene-butadiene resins, ethylcellulose, epoxy resins, and urethane resins; and latexes of these polymers. Among them, the binder is preferably gelatin or polyvinyl alcohol. The binder may be a binding resin described below.

The F toner may contain a binding resin used in conventional toners. In the case of a toner having a structure where photosensitive and thermosensitive capsules are dispersed in a base material, a binding resin may be used, for example, as the main component of the base material or as the material of the shells of the photosensitive and thermosensitive capsules. However, use of the binding resin is not limited thereto.

There is no particular limit to the type of the binding resin, and a known crystalline or amorphous resin may be used as such. In particular, a crystalline polyester resin having a narrow melting point range is useful in obtaining a low-temperature fixing property. Examples of the amorphous polymer (amorphous resin) include a known styrene-acrylic resin and a known polyester resin. The amorphous resin is preferably an amorphous polyester resin.

In addition, the F toner may further contain components other than the aforementioned. There is no particular limit to the types of other components, and other components may be selected properly according to the application of the F toner. Examples thereof include various known additives used in conventional toners such as a releasing agent, inorganic fine particles, organic fine particles, and a charge control agent.

The first and second components of the F toner usable in the invention may be colored before the color forming therebetween, but are preferably substantially colorless substances.

Hereinafter, a method of producing the F toner will be described briefly.

The F toner is preferably prepared by a known wet production method such as an aggregation/coalescence method. The wet production method is particularly preferable for preparation of a toner having a structure containing first and second components that react with each other to form a color, a photocurable composition, and microcapsules dispersed in the photocurable composition, wherein the first component is contained in the microcapsules and the second component in the photocurable composition.

The microcapsules used in the toner having such a structure are preferably heat-responsive microcapsules, but may be sensitive to other stimulus such as light.

Any one of known wet production methods may be used for production of the toner, but, among the wet production methods, use of an aggregation/coalescence method is preferably used. This is because it can be conducted at a reduced maximum processing temperature and easily provides toners having various structures.

When compared with conventional toners containing a pigment and a binder resin as main components, the toner having the aforementioned structure, which includes, in a large amount, a photocurable composition containing low-molecular weight components as main components, tends to be particles, which are formed in the process of granulation, having insufficient strength. Use of the aggregation/coalescnece method is also advantageous from this point, because it does not require high shearing force.

Generally, the aggregation/coalescence method includes: preparing dispersion liquids of various materials of a toner, forming agglomerates in a raw material dispersion liquid in which two or more of the dispersion liquids are mixed, and coalescing the agglomerates formed in the raw material dispersion liquid. The aggregation coalescence method may further include an adhesion step (coating layer-forming step) of adhering the component(s) of a coating layer to the surface of each of the agglomerates to form a coating layer between the aggregation and coalescence steps, if necessary.

Although the kinds and the combination of various dispersion liquids used as raw materials in producing an F toner may be different from those of the above-described general toners, the F toner can also be prepared by aggregation, and coalescence, and, optionally, adhesion.

For example, in the case of a toner having a structure where photosensitive and thermosensitive capsules are dispersed in a resin, a photosensitive and thermosensitive capsule dispersion liquid is prepared, or two or more photosensitive and thermosensitive capsule dispersion liquids that form different colors are prepared. Each dispersion liquid is prepared by mixing a dispersion liquid where microcapsules containing a first component are dispersed with a dispersion liquid where a photocurable composition containing a second component is dispersed to prepare a raw material dispersion liquid and to form primary agglomerates therein [first aggregation (a1)]; adding a first resin particle dispersion liquid where resin particles are dispersed to the raw material dispersion liquid containing the primary agglomerates so as to adhere the resin particles to the surfaces of the agglomerates [adhesion (b1)]; and heating the raw material dispersion liquid containing the agglomerates each having the resin particles on the surface thereof to coalesce the agglomerates and the resin particles and to prepare primary coalescence particles (photosensitive and thermosensitive capsules) [first coalescence (c1)].

When the one or more photosensitive and thermosensitive capsule dispersion liquids and a second resin particle dispersion liquid where resin particles are dispersed are mixed with each other to prepare a mixed liquid and to form secondary agglomerates therein [second aggregation (d1)], the mixed liquid containing the secondary agglomerates is heated to prepare secondary coalescence particles [second coalescence (e1)], and the secondary coalescence particles are taken out of the mixed liquid. Thus, the toner having a structure wherein photosensitive and thermosensitive capsules are dispersed in a resin is prepared.

Two or more kinds of photosensitive and thermosensitive capsule dispersion liquids are preferably used in the second aggregation. Photosensitive and thermosensitive capsules taken out of the one photosensitive and thermosensitive capsule dispersion liquid obtained through steps (a1) to (c1) may be used as a toner (i.e., toner containing only one color-forming portion).

In the case of a toner containing only one color-forming portion, the toner may be prepared by a production method the same as the above method except that the adhesion is replaced with the following: adding a releasing agent dispersion liquid where a releasing agent is dispersed to the raw material dispersion liquid containing the primary agglomerates so as to adhere the releasing agent to the surfaces of the agglomerates [first adhesion], and then adding a first resin particle dispersion liquid where resin particles are dispersed to the raw material dispersion liquid so as to adhere the resin particles to the surfaces of the agglomerates to which surfaces the releasing agent has adhered (second adhesion).

There is no particular limit to the volume-average particle diameter of the F toner for use in the invention. The volume-average particle diameter may be properly adjusted according to the structure of the toner and the kinds and the number of the color-forming portions contained in the toner.

However, when the toner contains about 2 to about 4 kinds of color-forming portions that can respectively form different colors (for example, when the toner includes three kinds of color-forming portions that can respectively form yellow, cyan, and magenta colors), the volume-average particle diameter of the toner, which depends on the structure of the toner, is preferably in the following range.

For example, when the toner has a structure where photosensitive and thermosensitive capsules (color-forming portion) are dispersed in a resin, the volume-average particle diameter of the toner is preferably in the range of about 5 to about 40 μm, and more preferably in the range of about 10 to about 20 μm. In this case, the volume-average particle diameter of the photosensitive and thermosensitive capsules is preferably in the range of about 1 to about 5 μm, and more preferably in the range of about 1 to about 3 μm.

When the toner has a volume-average particle diameter of less than 5 μm, the amount of the color-forming component(s) contained in the toner is small, which may result in deteriorated color reproducibility and a decreased image density. Meanwhile, when the toner has a volume-average particle diameter of more than 40 μm, an image with increased surface irregularity, uneven surface gloss, or deteriorated image quality may be obtained.

A toner with a structure, in which plural photosensitive and thermosensitive capsules are dispersed, tends to have a diameter larger than that of conventional small-diameter toners including a colorant (and having a volume-average particle diameter of approximately 5 to 10 μm). However, because the definition of an image is determined by the diameter of the photosensitive and thermosensitive capsules rather than the diameter of a toner, such a toner allows formation of a more precise image. In addition, the toner has excellent powder fluidity. Therefore, even when the amount of an external additive added to toner mother particles is small, the toner may have sufficient fluidity, and improved toner image forming and cleaning properties.

The diameter of a toner having only one color-forming portion can be more easily reduced than the diameter of the toner described above. The volume-average particle diameter of the toner having only one color-forming portion is preferably in the range of about 3 to about 8 μm, and more preferably in the range of about 4 to about 7 μm. When the toner has an excessively small volume-average particle diameter of less than 3 μm, the toner may have insufficient powder fluidity or insufficient durability. Meanwhile, when the toner has a volume-average particle diameter of more than 8 μm, the toner may not allow formation of a high-definition image.

Any of toners that can switch from a color-forming state (first state) to a non-color-forming state (second state) or vice versa by light irradiation, including an F toner, may be used in the invention, regardless of the components, the structure, and the color forming mechanism of the toner.

The toner for use in the invention preferably has a volume-average particle diameter distribution index GSDv of 1.30 or less and a ratio of the volume-average particle diameter distribution index GSDv to a number-average particle diameter distribution index GSDp (GSDv/GSDp) of 0.95 or more.

The volume-average particle diameter distribution index GSDv is more preferably 1.25 or less, and a ratio of the volume-average particle diameter distribution index GSDv to the number-average particle diameter distribution index GSDp (GSDv/GSDp) is more preferably 0.97 or more.

When the volume-average particle diameter distribution index GSDv is more than 1.30, an image with decreased definition may be obtained. Meanwhile, when a ratio of the volume-average particle diameter distribution index GSDv to the number-average particle diameter distribution index GSDp (GSDv/GSDp) is less than 0.95, such a toner has a deteriorated charging property, and scattering of toner or fogging, which causes image defects, occurs in some cases.

In the invention, the volume-average particle diameter, the volume-average particle diameter distribution index GSDv, and the number-average particle diameter distribution index GSDp of a toner are obtained as follows.

First, volume and number cumulative distribution curves are drawn on the basis of a toner particle size distribution measured with a measurement device such as COULTER MULTISIZER II (manufactured by Beckmann Coulter). The accumulation starts at the smallest of divided particle size ranges (channels). The particle diameters corresponding to an accumulation rate of 16% in the respective cumulative distribution curves are defined as a volume-average particle diameter D16v and a number-average particle diameter D16p, and the particle diameters corresponding to an accumulation rate of 50% are defined as a volume-average particle diameter D50v and a number-average particle diameter D50p. Similarly, the particle diameters corresponding to an accumulation rate of 84% are defined as a volume-average particle diameter D84v and a number-average particle diameter D84p. The volume-average particle size distribution index (GSDv) is defined as (D84v/D16v)^{1/2}, and the number-average particle size distribution index (GSDp) is defined as (D84p/D16p)^{1/2}. The volume-average particle size distribution index (GSDv) and the number-average particle size distribution index (GSDp) can be calculated from these relational expressions.

The volume-average particle diameter of microcapsules or photosensitive and thermosensitive capsules is measured with, for example, a laser-diffraction particle size distribution analyzer (LA-700 manufactured by Horiba, Ltd.).

The toner in the invention preferably has a shape factor SF1 of about 110 to about 130, and the shape factor SF1 is represented by the following Formula (1).

SF1=(ML²/A)×(n/4)×100 Formula (1)

In Formula (1), ML represents the maximum length (μm) of a toner particle; and A represents the projected area (μm²) of the toner particle.

When the toner has a shape factor SF1 of less than 110, the toner easily remains on an image-holding member in the transferring step of an image-forming method. The remaining toner needs to be removed. However, such a toner tends to have a deteriorated cleaning property when the remaining toner is removed with, for example, a blade. As a result, image defects may occur.

On the other hand, when the toner, which is contained in a developer, has a shape factor SF1 of more than 130, the toner may break due to collision between the toner and a carrier in a toner image-forming unit. As a result, a large amount of fine powder may occur, or the releasing agent contained in the toner may be exposed and may contaminate an image-holding member and may degrade the charging characteristics of the toner. In addition, the fine powder may cause fogging.

The shape factor SF1 is obtained by inputting the optical microscope images of toner particles scattered on a slide glass into a Luzex image analyzer (FT manufactured by Nireco Corporation) through a video camera, calculating the maximum length (ML) and the projected area (A) of each of fifty or more toner particles selected, calculating the shape factors of these toner particles from Formula (1), and averaging the calculated shape factors.

The toner for use in the invention may be used as a single-component developer, but is preferably used as a toner for two-component developer of a carrier and a toner.

To form an image of two or more colors with one developer, the developer preferably includes (1) a toner having two or more color-forming portions each of which contains a photocurable composition and microcapsules dispersed in the photocurable composition and that can form different colors, or is preferably (2) a mixture of two or more toners each of which has a color-forming portion containing a photocurable composition and microcapsules dispersed in the photocurable composition and that can form different colors.

For example, the former preferably contains three color-forming portions that can respectively form yellow, magenta and cyan colors. Meanwhile, the latter is preferably a mixture of toners that can respectively form yellow, magenta and cyan colors.

The carrier for use in the two-component developer preferably has cores and a resin layer that coats the surface of each of the cores. There is no particular limit to the material of the cores. Examples thereof include magnetic metals such as iron, steel, nickel, and cobalt; alloys made of at least one of these metals and at least one of manganese, chromium, and rare earth metals; and magnetic oxides such as ferrite and magnetite. The cores are preferably made of ferrite, especially, an alloy made of ferrite and at least one of manganese, lithium, strontium, and magnesium from the viewpoints of the surface properties and resistance of the cores.

The resin of the resin layer that coats the surface of each core is any of those usable as matrix resins, and otherwise there is no particular limit thereto. The resin of the resin layer is selected properly according to the application of the toner.

The blending ratio (mass ratio) of the toner usable in the invention to the carrier in the two-component developer is preferably in the range of approximately 1:100 to 30:100 and more preferably in the range of approximately 3:100 to 20:100.

Hereinafter, the image-forming device of the invention will be described.

In the image-forming device of the invention, a color image is formed by an electrophotographic process using an F toner.

However, there is no particular limit to the image-forming process in the image-forming device of the invention. The image-forming process may be a so-called electrophotographic process, a process (ionography) in which an electrostatic latent image is formed on a dielectric member by using ions, a process in which an electrostatic latent image is formed on a uniformly charged dielectric member by the heat of a thermal head according to image information, a process in which a magnetic latent image rather than an electrostatic latent image is formed and a toner image is then formed, or a process in which a sticky ink droplets are formed on an image-holding member according to image information to produce a toner image.

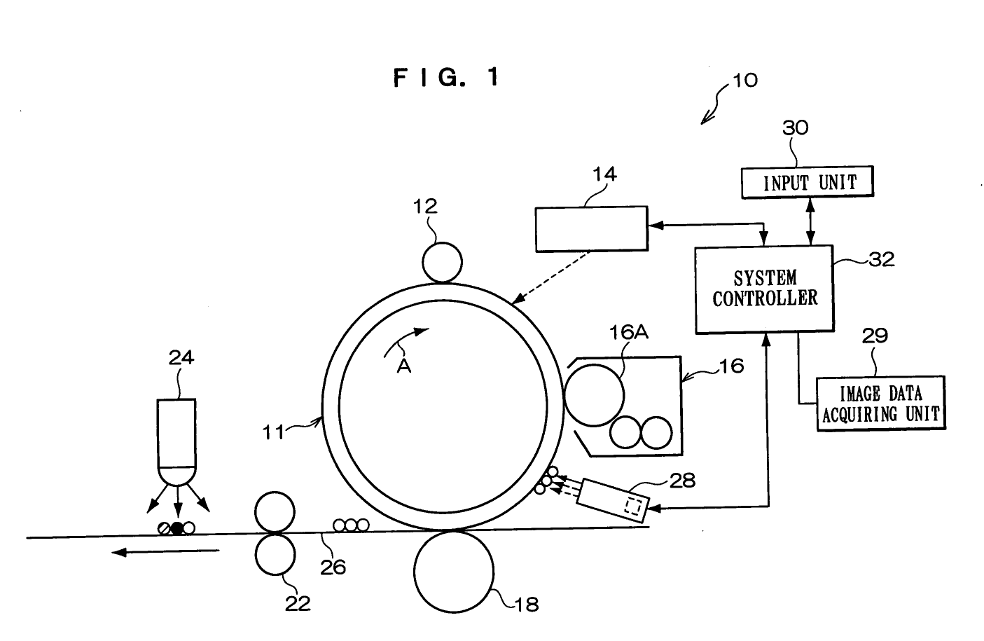

As shown in FIG. 1, the image-forming device 10 of an exemplary embodiment has a photoreceptor (image-holding member) 11 that may be used in an ordinary electrophotographic process. The photoreceptor 11 can rotate in a predetermined direction (direction indicated by arrow A in FIG. 1). A charging unit 12, an electrostatic latent image forming unit (light exposure unit) 14, a toner image forming unit 16, a color forming information applying unit 28, and a transfer unit 18 are provided near the outer circumferential surface of the photoreceptor 11 along the rotation direction of the photoreceptor 11. The image-forming device 10 also has an image data acquiring unit 29 for acquiring an image data according to the image of an original. The image data acquiring unit 29 may be an image reader that reads the image of an original to generate an image data according to the image, or a communication device that receives an image data according to the image of an original from an external member (e.g., a flexible disk) or an external device (e.g., other computer).

The photoreceptor 11 may be any one of known photoreceptors. For example, the photoreceptor may be a drum having a conductive substrate, and an inorganic photosensitive layer made of, for example, Se or a-Si, an organic photosensitive layer, or plural organic photosensitive layers on the conductive substrate. If the photoreceptor 11 is a belt, the photoreceptor may have a substrate made of a transparent resin such as PET or PC, and a desired thickness of the photoreceptor is determined by design conditions of the photoreceptor such as the diameters of rolls around which the photoreceptor belt is wound and the tension applied to the photoreceptor belt. The thickness of the photoreceptor is in the range of approximately 10 to 500 μm. The structure of the other layers in the photoreceptor belt is the same as in the photoreceptor drum.

When the photoreceptor 11 is irradiated with light emitted by the color forming information applying unit 28 from the back surface (internal surface) of the photoreceptor 11, a transparent photoreceptor having a substrate that is made of a transparent resin may be used as the photoreceptor 11. If the photoreceptor is transparent, the substrate of the photoreceptor is made of a material transparent with respect to the irradiated light.

The term “transparent” means that having a transmittance, or a ratio of the amount of outgoing light to that of incident light (outgoing light/incident light) is 50% or more in the wavelength region used. In this case, the material of the substrate is, for example, glass or a plastic substance, and an electrically conductive layer is formed on the outer surface of the substrate to form an electrode thereon. Alternatively, electrically conductivity may be given to the material of the substrate itself If the photoreceptor need not be transparent, the substrate may be a hollow cylinder made of a metal such as aluminum, which is ordinarily used, or a nickel seamless belt in addition to the transparent substrate described above.

The intensity of light of light exposure to apply color forming information or non-color forming information to a toner image is much higher than that for ordinary electrostatic latent image formation. Specifically, the amount of the energy of the light used to apply color forming information or non-color forming information to a toner image is approximately 1,000 times higher than light exposure (2 mJ/m²) applied to a photoreceptor in an ordinary electrophotographic process. When the photoreceptor 11 has a charge-generating layer whose sensitivity to light is about 1/1000 of that of the charge-generating layer of a conventional photoreceptor in this case, the intensity of the light of the light exposure to apply color forming information or non-color forming information to a toner image is balanced with the sensitivity of the charge-generating layer, preventing the light from damaging the photoreceptor 11.

It is preferable that the surface of the photoreceptor 11 has a function of preventing the light exposure to apply color forming information or non-color forming information to a toner image from degrading the photoreceptor 11. Specifically, it is effective to form, on the surface of the photosensitive layer of the photoreceptor, a surface layer that transmits only light used to form an electrostatic latent image and that reflects or absorbs light used to apply color forming information or non-color forming information to a toner image. The surface layer may be a dichroic mirror coat, which reflects the light used to apply color forming information or non-color forming information to a toner image, or a sharp cut filter where a light-absorbing substance is dispersed and that absorbs the light.

On the other hand, when a toner image is formed by ionography, a dielectric member is used in place of the photoreceptor 11. The dielectric member is also preferably transparent for a reason the same as the aforementioned.

The transparent dielectric member may be a product that is the same as the transparent photoreceptor except that the photosensitive layer is replaced with a transparent dielectric layer made of a transparent plastic material such as PET or PC.

The charging unit 12 electrically charges the outer circumferential surface of the photoreceptor 11 to a predetermined electric potential.

Any one of known charging devices may be used as the charging unit 12 that electrically charges the photoreceptor 11. A contact-type charging device may be a roll, a brush, a magnetic brush, or a blade. A non-contact-type charging device may be Corotron, or Scorotron. However, the charging unit 12 is not limited thereto.

Among them, a contact-type charger is used preferably from the viewpoint of well balance between a charging compensation ability and the amount of ozone generated. The contact-type charger electrically charges the surface of the photoreceptor 11 by applying a voltage to a conductive member brought into contact with the surface of the photoreceptor 11. In this case, the charging unit 12 has a conductive unit (not shown) and a voltage-applying unit (not shown) that applies a voltage to the conductive unit.

The conductive unit may be brush-, blade-, pin electrode-, or roll-shaped, but is preferably roll-shaped. Generally, a roll-shaped conductive unit has a resistance layer, an elastic layer that supports the resistance layer and that is disposed on the inner surface of the resistance layer, and a core disposed on the inner surface of the elastic layer. The unit may have, as needed, a protective layer on the outer surface of the resistance layer.

To electrically charge the photoreceptor 11 by using the conductive unit, the voltage-applying unit applies a voltage to the conductive unit, and the applied voltage is preferably a DC voltage, or a voltage obtained by superimposing an AC voltage on a DC voltage.

When charging is performed only with direct voltage, the voltage is preferably from a value whose absolute value is lower than a desired surface electric potential by approximately 500 V to a value whose absolute value is higher than the desired surface electric potential by approximately 500V. Specifically, the absolute value of the voltage is preferably in the range of about 700 to about 1,500 V. When an AC voltage is superimposed on a DC voltage, the direct current is preferably from a value lower than a desired surface electric potential by 50V to a value higher than the desired surface electric potential by 50V The voltage between peaks of the alternate voltage (Vpp) is preferably about 400 to about 1,800 V, and more preferably about 800 to about 1,600 V The frequency of the AC voltage is preferably about 50 to about 20,000 Hz, and more preferably about 100 to about 5,000 Hz. The AC voltage may have any of sinewaves, rectangular waves, and triangular waves.

The absolute value of the charging potential is preferably set in the range of about 150 to about 700 V.

The electrostatic latent image forming unit 14 irradiates the surface of the electrically charged photoreceptor 11 with light modulated on the basis of a composite image data described later to form an electrostatic latent image corresponding to the composite image data on the photoreceptor 11 in the image-forming device 10.

Any one of known light exposure devices may be used as the electrostatic latent image forming unit 14 that forms an electrostatic latent image on the photoreceptor 11. Examples thereof include a laser scanning system, an LED image bar system, an analog light-exposure unit, and an ion current control head. In addition, new light-exposure units that might be developed in the future may also be used, if they achieve the advantageous effects of the invention.

The wavelength of light to which the electrostatic latent image forming unit 14 exposes the photoreceptor 11 is preferably within the range in which the photoreceptor 11 has spectral sensitivity. Conventionally, the electrostatic latent image forming unit is mainly a near-infrared semiconductor laser having an oscillation wavelength around 780 nm, but may be a laser having an oscillation wavelength in the 600 s nm or a blue light-emitting laser having an oscillation wavelength within the range of about 400 to about 450 nm. In addition, a surface emitting laser source allowing multi-beam output is also effective as the electrostatic latent image forming unit 14 to form a color image. Alternatively, a light-emitting diode (LED) may be used as the electrostatic latent image forming unit 14.

When a full color image can be formed in the image-forming device 10, the composite image data includes, for example, a yellow (Y) color image-forming information data, a magenta (M) color image-forming information data and a cyan (C) color image-forming information data. In the case of reverse development in such a case, the irradiation by the electrostatic latent image forming unit 14 is conducted at a portion of the photoreceptor 11 where a toner image is to be formed (toner image formation portion) on the basis of the logical sum of the yellow, magenta and cyan color image-forming information data. Meanwhile, in the case of normal development in the above case, the irradiation by the electrostatic latent image forming unit 14 is conducted at a portion of the photoreceptor 11 which portion is other than the toner image formation portion on the basis of the logical sum described above.

The spot diameter of the irradiated light beams is preferably in the range of about 40 to about 80 μm to control the definition within the range of about 600 to about 1,200 dpi. The light exposure is preferably such that the electric potential at the exposed region of the photoreceptor 11 (hereinafter, referred to as a post-exposure electric potential in some cases) is in the range of about 5 to about 30% of the aforementioned charging potential. However, to control the amount of the toner used to form a toner image according to an image density, the light exposure is controlled according to the density (gradation value) for each exposure position in an exemplary embodiment.

In ionography, a latent image is formed on an image-holding member with an ion writing head. Examples of the ion writing head include a head that controls the direction of the ion current according to image signals (see JP-A No. H04-122654), and a head that controls generation of the ion current (see JP-A No. H06-99610).

The image-holding member used in ionography may be either a dielectric member or a photoreceptor.

The toner image forming unit 16 adheres a toner to the electrostatic latent image formed on the outer peripheral surface of the photoreceptor 11 to form, on the photoreceptor 11, a toner image corresponding to the electrostatic latent image.

The toner image forming unit 16 contains an F toner therein. The toner image forming unit 16 has a development roll 16A that holds the toner contained in the toner image forming unit 16 and supplies the toner to the surface of the photoreceptor 11.

Any one of known developing devices may be used as the toner image forming unit 16. Any one of developing methods including a two-component developing method where a toner and micro-particles called a carrier carrying the toner are used, a single-component developing method where only a toner is used, and developing methods where other additive(s) to improve at least one of the properties of a developer (i.e., a toner alone, or a combination of a toner and a carrier) such as a developing property is used in addition to the developer may be used in the toner image forming unit 16.

In the developing method, at least one of a development roll brought into contact with the photoreceptor 11 and a development roll that is not brought into contact with the photoreceptor 11 may be used to form a toner image. In the invention, a hybrid developing method where a single-component developing method is combined with a two-component developing method may also be used. Further, new developing member and method that might be developed in the future may also be used in the invention, if these achieve he advantageous effects of the invention.

The toner contained in the developer may be toner particles each having color-forming portions that can respectively form yellow, magenta and cyan colors, or a combination of toner particles each having a color-forming portion that can form a yellow color, those each having a color-forming portion that can form a magenta color and those each having a color-forming portion that can form a cyan color.

The amount of the toner used to form a toner image (amount of the toner adhering to the photoreceptor) depends on an image to be formed. However, when a solid toner image is to be formed, the amount of the toner used to form the toner image is preferably in the range of about 3.5 to about 8.0 g/m², and more preferably in the range of about 4.0 to about 6.0 g/m².

The thickness of a toner image is preferably kept equal to or less than a certain value. This is because light used to apply color forming information and non-color forming information to the toner image needs to reach the deepest portion of the toner image. Specifically, for example, a solid toner image preferably has at most three toner layers, and more preferably has at most two toner layers. The number of the at least one toner layer of the toner image is obtained by measuring the thickness of a toner image actually formed on the surface of a photoreceptor 11 and by dividing the measured thickness by the number-average particle diameter of the toner.

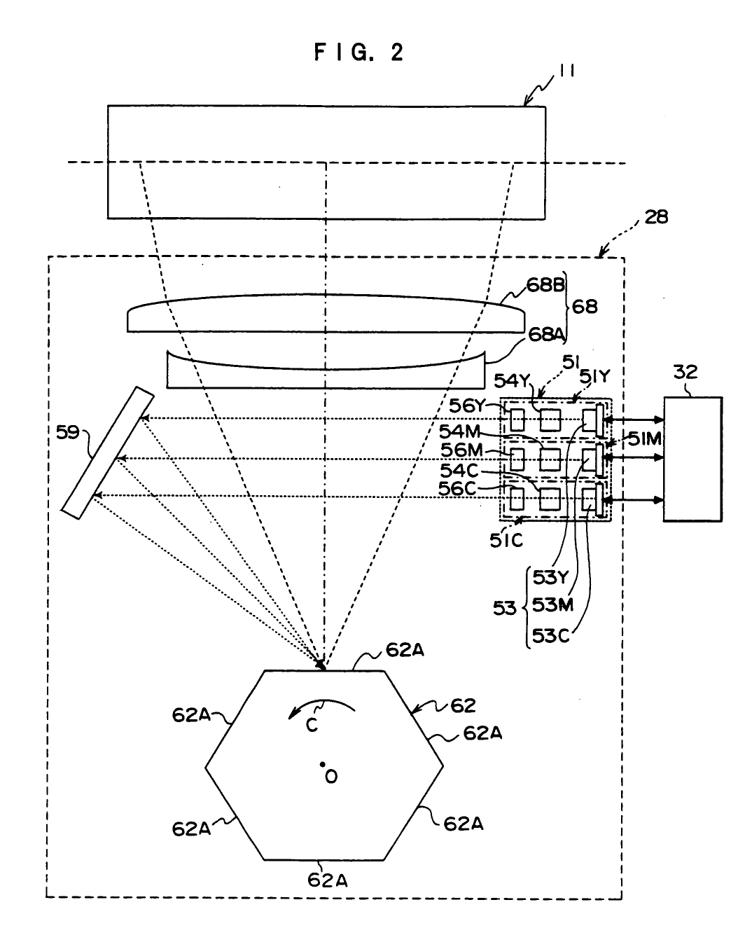

When an image to be formed has at least two colors, the color forming information applying unit 28, which has a light source 53 (not shown in FIG. 1, but shown in FIG. 2) emitting light with predetermined wavelengths to enable or inhibit formation of respective colors, irradiates the toner image formed on the photoreceptor 11 with the light from the light source 53. When an image to be formed is monochromic (one color), the color forming information aplying unit 28, which has a light source emitting light having a predetermined wavelength to enable or inhibit formation of the color, irradiates the toner image formed on the photoreceptor 11 with the light from the light source. As a result, a region of the toner image which region corresponds to the glossing region is in the second state (a non-color-forming state), and an image corresponding to the image of an original can be formed in the other region of the toner image.

FIG. 1 shows that the color forming information applying unit 28 is provided between the toner image forming unit 16 and the transfer unit 18 disposed downstream from the toner image forming unit 16 in the rotation direction of the photoreceptor 11. However, the color forming information applying unit 28 may be provided downstream from the transfer device 18 in the conveying direction of a recording material 26.

As shown in FIG. 2, the color forming information applying unit 28 scan-irradiates light on the outer circumferential surface of the photoreceptor 11 along the direction parallel to the rotation axis of the photoreceptor 11.

The color forming information applying unit 28 has a light irradiation unit 51 containing a light source 53 that emits light having particular wavelengths, a reflection mirror 59 for reflecting the light emitted from the light source 53, a rotary polygon mirror 62 for reflecting the light reflected by the reflection mirror 59 toward the photoreceptor 11, and an fθ lens 68.

The light irradiation unit 51 has light irradiation units that can emit light having wavelengths to enable or inhibit formation of the colors that can be respectively formed by the color-forming portions of the toner contained in the toner image forming unit 16. In an exemplary embodiment, the toner has three color-forming portions that respectively form Y, M, and C colors. In this case, the light irradiation unit 51 has three light irradiation units: a Y-color irradiation unit 51Y corresponding to the Y color-forming portion, an M-color irradiation unit 51M corresponding to the M color-forming portion, and a C-color irradiation sub-unit 51C corresponding to the C color-forming portion. However, the invention is not limited to such a configuration. For example, when the toner has only one color-forming portion, the light irradiation unit 51 may emit only light having a wavelength to enable or inhibit formation of the color that can be formed by the one color-forming portion.

The Y-color irradiation unit 51Y has a light source 53Y The light source 53Y emits light having a predetermined wavelength to enable or inhibit formation of a yellow color on the basis of a Y color component information data for color forming information and non-color forming information application described later. The wavelength of the light emitted from the light source 53Y is previously set to the wavelength corresponding to the maximum spectral sensitivity of the Y color-forming portion. In addition, the Y-color irradiation unit 51Y further has a collimator lens 54Y and a cylinder lens 56Y in that order along the traveling direction of the light emitted from the light source 53Y The turning-on or turning-off of the light source 53Y is controlled by a system controller 32 (the details of which will be described later) according to the Y color component information data for color forming information and non-color forming information application, and light modulated according to the Y color component information data for color forming information and non-color forming information application is emitted. The light emitted from the light source 53Y is substantially collimated by the collimator lens 54Y, converged by the cylinder lens 56Y, and then reflected by the reflection mirror 59 onto the rotary polygon mirror 62.

Similarly, the M-color irradiation unit 51M has a light source 53M. The light source 53M emits light having a predetermined wavelength to enable or inhibit formation of a magenta color on the basis of an M color component information data forcolor forming information and non-color forming information application described later. The wavelength of the light emitted from the light source 53M is previously set to the wavelength corresponding to the maximum spectral sensitivity of the M color-forming portion.

In addition, the M-color irradiation unit 51M further has a collimator lens 54M and a cylinder lens 56M in that order along the traveling direction of the light emitted from the light source 53M. The turning-on or turning-off of the light source 53M is controlled by the system controller 32 according to the M color component information data for color forming information and non-color forming information application, and light modulated according to the M color component information data for color forming information and non-color forming information application is emitted.

The light emitted from the light source 53M is substantially collimated by the collimator lens 54M, converged by the cylinder lens 56M, and then reflected by the reflection mirror 59 onto the rotary polygon mirror 62.

Similarly, the C-color irradiation unit 51C has a light source 53C. The light source 53C emits light having a predetermined wavelength to enable or inhibit formation of a cyan color on the basis of a C color component information data for color forming information and non-color forming information application described later. The wavelength of the light emitted from the light source 53C is previously set to the wavelength corresponding to the maximum spectral sensitivity of the C color-forming portion.

In addition, the C-color irradiation unit 51C further has a collimator lens 54C and a cylinder lens 56C in that order along the traveling direction of the light emitted from the light source 53C. The turning-on or turning-off of the light source 53C is controlled by the system controller 32 according to the C color component information data for color forming information and non-color forming information application, and light modulated according to the C color component information data for color forming information and non-color forming information application is emitted. The light emitted from the light source 53C is substantially collimated by the collimator lens 54C, converged by the cylinder lens 56C, and then reflected by the reflection mirror 59 onto the rotary polygon mirror 62.

Hereinafter, the entirety of the light sources 53Y, 53M, and 53C will be called the light source 53.

The rotary polygon mirror 62 is equilaterally polygonal (equilaterally hexagonal in this exemplary embodiment) and has plural reflective planes 62A as side walls. The rotary polygon mirror 62 is rotated by a motor (not shown) around its rotating shaft O serving as a rotation center in the direction indicated by arrow C at a predetermined speed.

Light entering the rotary polygon mirror 62 is converged on reflection planes 62A of the rotary polygon mirror 62. The light is reflected by the reflection planes 62A so that the incident angle of light entering each of the reflection planes 62A is changed continuously by rotation of the rotary polygon mirror 62. In this way, the photoreceptor 11 is scan-irradiated with light beams in the direction parallel to the axis of the photoreceptor 11.

On the path along which the reflected light by the rotary polygon mirror 62 advances, the fθ lens 68 including a first lens 68A and a second lens 68B and serving as a scanning lens system is provided. The light beams reflected by the rotary polygon mirror 62 pass through the fθ lens 68 and are thereby converged in the main scanning direction of the photoreceptor 11 and pass through a cylinder lens (not shown) and are thereby converged in the sub-scanning direction, forming an image on the photoreceptor 11.

Each of the light sources 53Y, 53M, and 53C needs to be capable of emitting light having the respective wavelengths to switch toner particles located in a region of a toner image which region is to be colored from the second state (non-color-forming state) to the first state (color-forming state) or to switch toner particles located in the other region of the toner image which other region is not to be colored from the first state to the second state at a predetermined definition at a predetermined intensity. Otherwise there is no particular limit to the light sources.

However, irradiation of a toner with light emitted by the light source 53 should be performed at an intensity significantly higher than that of light emitted by the electrostatic latent image forming unit 14 to form the electrostatic latent image. Specifically, the energy amount of the light for color forming information and non-color forming information application needs to be approximately 1,000 times higher than the light exposure (2 mJ/m²) on the photoreceptor used in an ordinary electrophotographic process. To attain this, a light source that can emit light at an intensity higher than that of light for forming an electrostatic latent image should be used as the light source 53.

For example, the light exposure of light necessary for color forming information and non-color forming information application is preferably in the range of about 0.05 to about 0.8 mJ/cm², and more preferably in the range of about 0.1 to about 0.6 mJ/cm². In particular, the light exposure needed is correlated with the amount of a toner used to form a toner image. For example, irradiation at a light exposure of about 0.2 to about 0.4 mJ/m² is preferably conducted when the amount of a toner used to form a toner image (solid image) is approximately 5.5 g/m².

Each of the light sources 53Y, 53M, and 53C attaining such a light exposure may be an LED image bar, or a laser ROS. The spot diameter of the light beams irradiated on the toner image formed on the photoreceptor 11 is preferably about 10 to about 300 μm, and more preferably about 20 to about 200 μm to obtain an image with a definition of about 100 to about 2,400 dpi.

The wavelength of light for application of color forming information and non-color forming information to the F toner depends on the design of the materials of the toner used, as described previously. For example, when the F toner is an optical color-forming toner having color-forming portions that respectively form yellow, magenta and cyan colors, the Y-color irradiation unit 51Y is turned on to irradiate regions of a toner image formed on the photoreceptor 11 which regions are to be colored yellow with light having a wavelength of 405 nm (hereinafter, referred to as λA light) according to the Y color component information data for color forming information and non-color forming information application to form a yellow color (Y color), and the M-color irradiation unit 51M is turned on to irradiate regions of the toner image which regions are to be colored magenta with light having a wavelength of 535 nm (hereinafter, referred to as λB light) according to the M color component information data for color forming information and non-color forming information application to form a magenta color (M color), and the C-color irradiation unit 51C is turned on to irradiate regions of the toner image which regions are to be colored cyan with light having a wavelength of 657 nm (hereinafter, referred to as λC light) according to the C color component information data for color forming information and non-color forming information application to form a cyan color (C color).

Two of the λA light, the λB and the light λC is used together for formation of a secondary color, and turning on and turning off of each of the Y-color irradiation unit 51Y, the M-color irradiation unit 51 M, and the C-color irradiation unit 5 IC is controlled. For example, regions to be colored red (R color) are irradiated with both the λA light and the λB light, regions to be colored green (G color) are irradiated with both the λA light and the λC light, and regions to be colored blue (B color) are irradiated with both the light λB and the light λC. Regions to be colored black (K color) are irradiated with the light λA, the light λB and the light λC. Regions not to be colored are irradiated with none of the light λA, the light λB and the light λC.

On the other hand, when the toner is a non-optical color-forming toner having color-forming portions that respectively form yellow, magenta and cyan colors, regions of a toner image formed on the photoreceptor 11 which regions are not to be colored yellow with light having a wavelength of 405 nm (hereinafter, referred to as λA light) according to the Y color component information data for color forming information and non-color forming information application to hinder formation of a yellow color (Y color), and regions of the toner image which regions are not to be colored magenta with light having a wavelength of 535 nm (hereinafter, referred to as λB light) according to the M color component information data for color forming information and non-color forming information application to hinder formation of a magenta color (M color), and regions of the toner image which regions are not to be colored cyan with light having a wavelength of 657 nm (hereinafter, referred to as λC light) according to the C color component information data for color forming information and non-color forming information application to hinder formation of a cyan color (C color).

Two of the λA light, the λB and the light λC is used together for formation of a secondary color. Regions to be colored red (R color) are irradiated with the λC light, and regions to be colored green (G color) are irradiated with the λB light, and regions to be colored blue (B color) are irradiated with the light LA. Regions to be colored black (K color), which is a tertiary color, are irradiated with none of the light λA, the light λB and the light λC. Regions not to be colored are irradiated with the light λA, the light λB and the light λC.

The light from the color forming information applying unit 28 may be modulated by a known image-modulating method, such as a pulse width-modulating method, or an intensity modulating method, or combination thereof, if necessary.

The mechanism of forming a full-color image by using the color forming information applying unit 28 in the exemplary embodiment has been described. However, in the exemplary embodiment, color forming information and non-color forming information may be applied to the toner image to form a monochrome image having only one color, for example, yellow, magenta, or cyan. In this case, light having only one particular wavelength to enable or inhibit formation of the corresponding color (e.g., yellow, magenta or cyan) is emitted by the color forming information applying unit 28. Other preferred conditions in this case are the same as those in forming a full-color image.

In the image-forming device 10 of FIG. 1, the toner image is irradiated to apply color forming information and non-color forming information thereto after toner image formation by the toner image forming unit 16 and before transfer of the resultant toner image onto a recording material 26. However, the color forming information and the non-color forming information may be applied at least before fixing of the toner image onto the recording material 26. For example, the color forming information and the non-color forming information may be applied to a toner image transferred onto a recording material 26 by the color forming information applying unit 28.

However, when the color forming information and the non-color forming information is applied to the toner image transferred onto a recording material 26 by the color forming information applying unit 28, the surface smoothness of the recording material 26 and accuracy of positions of a desired image which positions are to be colored are required. Therefore, application of the color forming information and the non-color forming information is preferably conducted after adhesion of a toner to an electrostatic latent image by the toner image forming unit 16 and before transfer of the resultant toner image onto a recording material 26.

The toner image to which the color forming information and the non-color forming information has been applied has only an inherent color and no formed color. For example, when the toner contains a sensitizing dye, the toner image has only the color tone of the sensitizing dye.

The transfer unit 18 transfers the toner image from the photoreceptor 11 to a recording material 26.

Any one of known transfer devices may be used as the transfer unit 18. For example, when the transfer unit 18 is a contact-type unit, the transfer unit 18 may be a roll, a brush, or a blade. When the transfer unit 18 is a non-contact-type unit, the transfer unit 18 may be Corotron, or Scorotron. Alternatively, the toner image may be transferred by using pressure, or pressure and heat.

The absolute value of the transfer bias is preferably in the range of about 300 to about 1,000 V. An alternate voltage (Vpp of about 400 V to about 4 kV, and frequency of about 400 to about 3 kHz) may be superimposed on the DC transfer bias.

When a recording material 26 stored in a recording material-supplying unit (not shown) is fed to the position (transfer zone) sandwiched between the photoreceptor 11 and the transfer unit 18 and sandwiched and conveyed by the photoreceptor 11 and the transfer unit 18, the toner image on the photoreceptor 11 is transferred onto the recording material 26.

The fixing unit 22 fixes the toner image on the recording material 26.

The fixing unit 22 also serves as a color forming unit for forming the specific color in a toner image in the exemplary embodiment. Alternatively, a post-fixing irradiating unit 24 may also be used as the color forming unit.

By applying color forming information and non-color forming information to a toner image, a specific color is formed in the region of the toner image which region is in a color-forming state (first state) by applying heat of the fixing unit 22 to the toner image.

Any one of known fixing devices may be used as the fixing unit 22. When the fixing unit is, for example, a heating unit and/or a pressurizing unit, such a unit may be a roll or a belt. The heat source of the heating unit may be a halogen lamp, or IH. The fixing unit is compatible with various paper-feeding passes such as a straight pass, a rear C pass, a front C pass, an S pass, and a side C pass.

In the exemplary embodiment, the fixing unit 22 is responsible for forming a specific color in the toner image transferred onto the recording material 26 and fixing the toner image on the recording material 26, but the color forming and the fixing may be performed separately.

In the latter case, the image-forming device of the exemplary embodiment may have a separate color forming unit for forming a specific color in the toner of the toner image transferred onto the recording material 26.

There is no particular limit to the position where the color forming unit is provided. For example, the color forming unit is provided before the fixing unit 22.

When separate units form a specific color in the toner image transferred onto the recording material 26 and fix the toner image onto the recording material 26, respectively, it becomes possible to separately control the heating temperature during the color forming and the heating temperature during fixing the toner image on the recording material 26. As a result, the degree of freedom in designing the color-forming material and the toner binder material may be improved.

In this case, color forming method and unit may be selected from various methods and devices according to the color forming mechanism of toner particles. For example, the color forming unit may irradiate a toner image with light having a particular wavelength to harden or optically decompose a substance in the toner which substance relates to color forming, or may pressurize a toner image to break capsules included in the toner image and containing color-forming particles. Thus, a color may be formed in an F toner.

However, the chemical reaction to form the color in an F toner to which color forming information and non-color forming information have been applied utilizes migration and diffusion, and the speed of the chemical reaction is generally slow. Therefore, it is necessary to apply sufficient diffusion energy to the toner in any of methods conducted in the above color-forming units. Thus, a method of heating a toner image to accelerate color-forming reaction is the most advantageous for color forming of the F toner. For this reason, color forming of a toner image transferred onto a recording material 26 and fixing the toner image on the recording material 26 are preferably performed simultaneously by the fixing unit 22. This is also preferable from the viewpoint of reduction in space.

The post-fixing irradiating unit 24 (optical fixing unit) stabilizes the formed color of the toner fixed on the recording material 26.

The post-fixing irradiating unit 24 can decompose reactive substances remaining in a non-color-forming region that is kept in a non-color-forming state, or can cause the reactive substances in the non-color-forming region to lose their reactivities. Therefore, the post-fixing irradiating unit 24 can ensure suppression of variation in color balance after image formation or can decolorize a background color.

In the exemplary embodiment, light irradiation of the post-fixing irradiating unit 24 is performed after the toner image is fixed on the recording material 26. However, when fixing the toner image is conducted, for example, by pressurizing the toner image rather than heat-melting the toner image, the light irradiation by the post-fixing irradiating unit 24 may be performed before the toner image is fixed on the recording material 26.

The post-fixing irradiating unit 24 emits light that can suppress undesired progress of color forming of the toner, and any one of known lamps such as a fluorescent lamp, an LED, or an EL may be used as such.

When the F toner used in the invention has three color-forming portions, the light from the post-fixing irradiating unit 24 preferably has three wavelengths respectively corresponding to the color-forming portions. In addition, the illuminance of the light is preferably in the range of approximately 2,000 to approximately 200,000 lux, and the irradiation time is preferably in the range of approximately 0.5 to approximately 60 seconds.

In the image-forming device 10 of the exemplary embodiment, a toner image formed on a photoreceptor 11 is transferred onto a recording material 26. However, the toner image formed on the photoreceptor 11 may be transferred onto an intermediate transfer member such as intermediate transfer belt, and the toner image transferred on the intermediate transfer member is then transferred onto the recording material 26.

Since color forming information and non-color forming information applied to the toner image is preserved stably in the image-forming device 10 of the exemplary embodiment, which has been described, it is unnecessary to consider a period from the application of the color forming information and the non-color forming information to the toner image to the color forming of the toner image. Therefore, the image-forming device 10 can comply with designs of devices with a wide speed range.

Specifically, the linear velocity is preferably in the range of about 10 to about 500 mm/sec, and more preferably in the range of about 50 to about 300 mm/sec. Even when an image is formed at such a linear velocity, the exposure period to apply color forming information and non-color forming information to a toner image may be determined on the basis of the linear velocity and definition.

Stable preservation of color forming information and non-color forming information applied to a toner also has excellent effects on stability of color tone of an image and reproducibility of a highlighted image, and therefore contributes to high-quality and high-reliability reproduction of a full-color image from an image data according to the image of an original.

The image-forming device 10 further has a system controller 32 that controls the whole of the image-forming device 10. The system controller 32 is electrically connected to the electrostatic latent image forming unit 14, the color forming information applying unit 28, and an input unit 30 by which various data is inputted into the image-forming device 10, so that data and signals are sent and received therebetween. The image-forming device 10 is also electrically connected to other units contained therein so that signals are sent and received therebetween.

The input unit 30 is, for example, a keyboard or a touch panel, which users utilize to input various data into the image-forming device 10, and operation instruction signals are inputted into a controller 46 by a user via the input unit 30. The input unit 30 may also be a communication device for receiving various data from external devices.

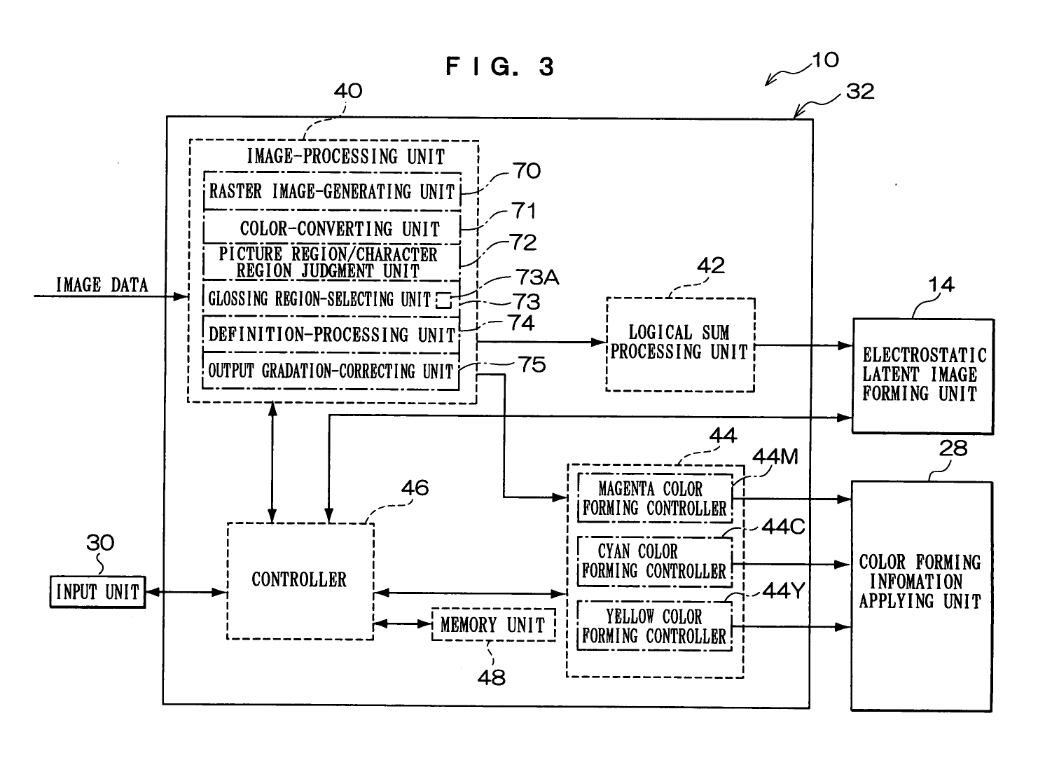

As shown in FIG. 3, the system controller 32 has an image-processing unit 40, a logical sum-processing unit 42, a color forming controller 44, a memory unit 48 for storing process-routines and various kinds of data, and the controller 46.

Each of the image-processing unit 40, the color forming controller 44, and the memory unit 48 is electrically connected to the controller 46 so that data and signals are sent and received therebetween. The controller 46 is also electrically connected to the input unit 30, the electrostatic latent image forming unit 14 and the color forming information applying unit 28 so that data and signals are sent and received therebetween.

The controller 46 controls each of the components in the image-forming device 10.

The image-processing unit 40 has a raster image-generating unit 70, a color-converting unit 71, a picture region/character region judgment unit 72, a glossing region-selecting unit 73, a definition-processing unit 74, and an output gradation-correcting unit 75.

When the image data according to the image of an original (original image data) and acquired in the image-forming device 10 is PDL data, the raster image-generating unit 70 converts the original image data into a raster image data. In other words, the PDL (page description language) code data is converted into a bit map image data by the raster image-generating unit 70.

The color-converting unit 71 converts the bit map data, into which the raster image-generating unit 70 has converted the original image data and that is an image data regarding the RGB color space, into an image data regarding the L*a*b* color space which image data does not depend on the types of devices, and then converts the image data regarding the L*a*b* color space into an image data regarding the YMCK color space.

The conversion of the image data regarding the RGB color space into that regarding the L*a*b* color space is performed by, for example, in advance storing a three-dimensional lookup table (DLUT)(three-dimensional LUT for color correction) in the memory unit 48 and reading out the DLUT. The conversion of the image data regarding the L*a*b* color space into that regarding the YMCK color space may be performed by causing the output gradation-correcting unit 75 to output a color patch described later, preparing a printer model correlating values of the L*a*b* color space with those of the YMCK color space, and using the color patch. The printer model may be prepared, for example, according to a neural network model, multiple regression or Neugebauer theoretical equation. However, there is no particular limit to the production manner of the printer model. In the color-converting unit 71, the conversion of the image data regarding the RGB color space into that regarding the YMCK color space is performed by using the printer model thus prepared.

The picture region/character region judgment unit 72 distinguishes picture and character regions of an image corresponding to the acquired original image data. The picture region represents a graphic or a photographic, and the character region contains at least one character.

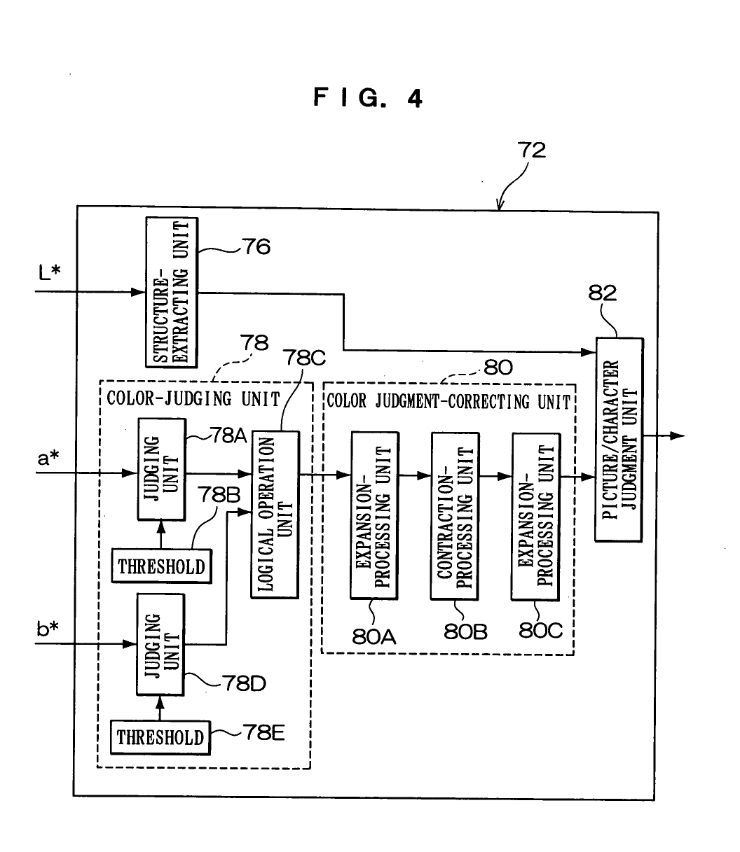

As shown in FIG. 4, the picture region/character region judgment unit 72 includes a structure-extracting unit 76, a color-judging unit 78, a color judgment-correcting unit 80, and a picture/character judgment unit 82.

When the image data regarding the L*a*b* color space converted by the color-converting unit 71 is inputted into the picture region/character region judgment unit 72, a hue signal L* is inputted into the structure-extracting unit 76. The structure-extracting unit 76, for example, extracts character structures from their edges and dotted photographic structures from their dot patterns, and, as a result, distinguishes character structures from picture structures such as a photograph, a graphic, or a background.

The chroma signal a* and the lightness signal b* of each of the pixels of the image corresponding to the acquired original image data is inputted into the color-judging unit 78. The color-judging unit 78 has a judgment unit 78A into which the chroma signal a* is inputted, a judgment unit 78D into which the lightness signal b* is inputted, and a logical operation unit 78C.

The judgment unit 78A compares the chroma signal a* with a threshold value 78B previously stored in the memory unit 48, and the judgment unit 78D compares the lightness signal b* with a threshold value 78E previously stored in the memory unit 48. When the judgment unit 78A judges from the comparison result that the chroma signal a* relates to a color pixel and/or the judgment unit 78D judges from the comparison result that the lightness signal b* relates to a color pixel, the logical operation unit 78C judges that the pixel corresponding to the chroma signal a* and the lightness signal b* is a color pixel. On the other hand, when the judgment unit 78A judges from the comparison result that the chroma signal a* does not relate to a color pixel and the judgment unit 78D judges from the comparison result that the lightness signal b* does not relate to a color pixel, the logical operation unit 78C judges that the pixel corresponding to the chroma signal a* and the lightness signal b* is a non-color pixel. Thus, the color-judging unit 78 judges whether each of pixels corresponding to chroma and lightness signals is a color pixel or a non-color pixel, regardless of whether an image of the pixels is a character or a photograph.

In addition, the color judgment-correcting unit 80 corrects results provided by the color-judging unit 78 to eliminate misjudged regions in the character structures.

The color judgment-correcting unit 80 includes an expansion-processing unit 80A, a contraction-processing unit 80B, and an expansion-processing unit 80C. The expansion-processing unit 80A, the contraction-processing unit 80B, and the expansion-processing unit 80C sequentially process the results from the color-judging unit 78 in that order.

When a window having a predetermined size (for example, 3×3 pixels) includes at least one pixel each of which is judged to be a color pixel, the expansion-processing unit 80A expands the pixel with a logical filter. Therefore, when a character structure has, for example, extremely low chroma and therefore has a missing portion, the expansion makes it possible to correct the missing portion.

The contraction-processing unit 80B processes a window having a predetermined size (for example, 5×5 pixels) to remove color pixels previously processed by the expansion-processing unit 81A and separate from but near, for example a black character.

The expansion-processing unit 80C performs processing that is the same as that in the expansion-processing unit 80C except that the window size is changed to another predetermined value (for example, 11×11 pixels).

Thus, the expansion-processing unit 80C expands a color pixel region by the number of pixels contracted (removed) by the contraction-processing unit 80B and the number of pixels that are in the vicinity of, for example, a low-chroma character and that have not been judged to be color pixels.

The picture/character judgment unit 82 distinguishes character and picture regions from the result of the character or picture structure extracted by the structure-extracting unit 76 and the results of the color judgment corrected by the color judgment-correcting unit 80, and outputs the judgment result to the glossing region-selecting unit 73.

In this way, the picture/character judgment unit 82 can distinguish a picture region, such as a photograph or a graphic, from a character region, such as a character, contained in an image to be formed by the image-forming device 10.

The glossing region-selecting unit 73 selects, as a glossing region, a region touching and surrounding the region that the picture region/character region judgment unit 72 has judged to be a picture region such as a photograph or a graphic image.

Specifically, the glossing region-selecting unit 73 has a memory unit 73A, and the memory unit 73A stores image-type information indicating at least one type of region that may be contained in an image corresponding to the original image data, and the periphery of which is to be selected as a glossing region. In the exemplary embodiment, the image-type information stored in the memory unit 73A indicates a picture region.

The glossing region-selecting unit 73 selects a region touching and surrounding a region whose type is the same as any one of the at least one type of region indicated by the information.

The glossing region-selecting unit 73 generates a glossing region data on the basis of the selected glossing region.

The image corresponding to the original image data may contain at least one of picture regions each corresponding to a graphic or a photographic, and character regions corresponding to characters.

When an image to be formed by the image-forming device 10 includes at least one picture region, the glossing region-selecting unit 73 selects, as the glossing region, a region touching and surrounding at least one of the at least one picture region in the exemplary embodiment. However, the glossing region may be a region other than the above.

The image-type information indicating the type of an image region serving as a standard in selecting the glossing region may be inputted by a user via the input unit 30, and the inputted image-type information may be stored in the memory unit 73A under control of the controller 46. In this case, the input unit 30 is, for example, a touch panel, and the controller 46 instructs the input unit 30 to display kinds of regions, to display that at least one of which should be selected by a user as a standard in selecting the glossing region and to display information requesting the user to touch at least one region of the display surface of the input unit 30 which at least one region corresponds to the kind of region to be selected as the standard. The user touching at least one region may input the image-type information into the image-forming device 10.

In this way, the image-forming device 10 allows the user to select a desired region as the glossing region.

The definition-processing unit 74 subjects an image data to, for example, processing to smoothen or emphasize an image corresponding to the image data. The output gradation-correcting unit 75 performs nonlinear gamma conversion, which is optimized according to output characteristics of the image such as a dot shape or the kind of a sheet of paper, for each of the at least one color component data of the image data subjected to the above processing in the definition-processing unit 74. The nonlinear gamma conversion may be performed according to, for example, a one-dimensional lookup table (LUT).

The image data processed by the image-processing unit 40 are inputted to the logical sum-processing unit 42 under control by the controller 46. Upon receipt of the image data from the image-processing unit 40, the logical sum-processing unit 42 calculates the logical sum of the CMYK data for each pixel, and outputs the calculated logical sum data into the electrostatic latent image forming unit 14. The electrostatic latent image forming unit 14 irradiates the surface of the photoreceptor 11 with light on the basis of the inputted logical sum data.

The image data from the image-processing unit 40 is inputted to the color forming controller 44 as well as the logical sum-processing unit 42.

The color forming controller 44 includes a magenta color forming controller 44M for controlling magenta color forming, a cyan color forming controller 44C for controlling cyan color forming, and a yellow color forming controller 44Y for controlling yellow color forming.

The color forming controller 44 has color forming controllers for respectively controlling cyan, magenta, and yellow color formations in this exemplary embodiment, as described above. Here, the color forming controller 44 should have color forming controllers corresponding to the light sources 53Y, 53M and 53C that emit light of different wavelengths that can change the corresponding one of the color-forming portions of an F toner from a color-forming state (first state) to a non-color-forming state (second state) or vice versa. For example, when the F toner further has a black color-forming portion and the light source 53 may further have a light source emitting light that has a specific wavelength and that switch the black color-forming portion from a color-forming state to a non-color-forming state or vice versa, the color forming controller 44 further has a black color forming controller.

The magenta color forming controller 44M, the cyan color forming controller 44C, and the yellow color forming controller 44Y respectively output an M color component information data, a C color component information data, and a Y color component information data into the color forming information applying unit 28 under control by the controller 46.

The light source 53 in the color forming information applying unit 28 is so controlled by the controller 46 as to emit light with wavelengths respectively corresponding to magenta, cyan and yellow color formations according to the M, C and Y color component information data.

As described above, an electrostatic latent image corresponding to the image of an original and a glossing region is formed on the photoreceptor 11 and color forming information and non-color forming information are applied to the toner image obtained by adhering a toner to the electrostatic latent image under control by the controller 46 in the image-forming device 10 of to the exemplary embodiment.

Hereinafter, processes executed in the controller 46 of the image-forming device will be described.

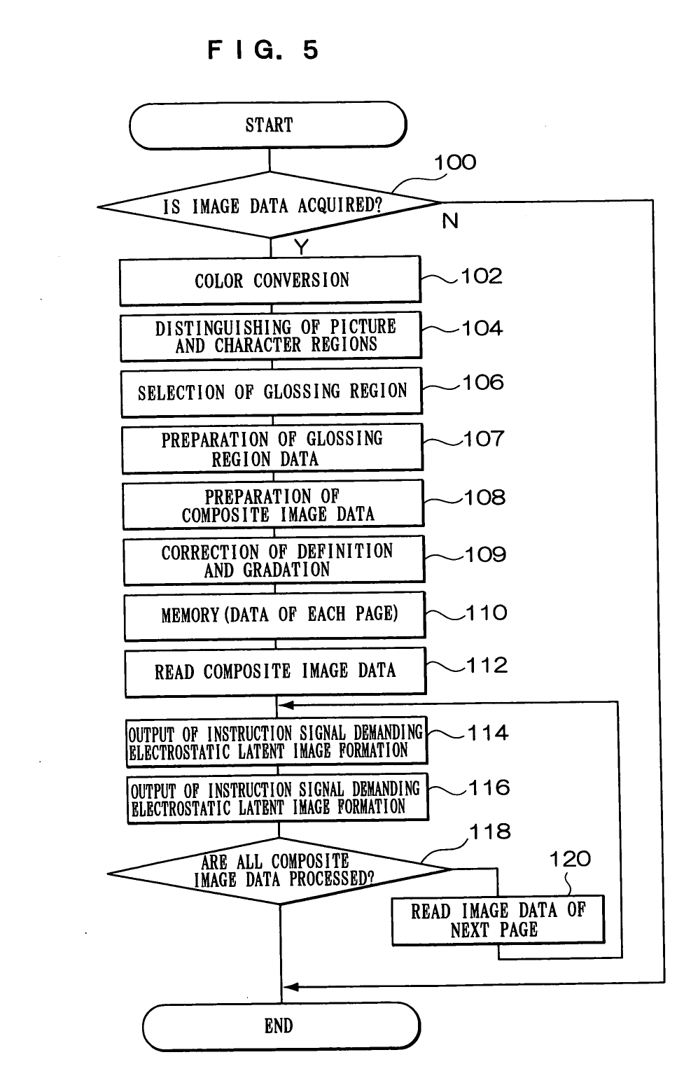

In the controller 46, the processing routine shown in FIG. 5 is executed at predetermined time intervals, and execution of Step 100 is started first. In Step 100, the controller 46 judges whether an original image data is acquired. When an original image data is not acquired, the processing routine ends. When an original image data is acquired, the processing proceeds to Step 102.

In Step 102, the controller 46 outputs a signal to instruct the raster image-generating unit 70 to generate a raster image data, and outputs a signal to instruct the color-converting unit 71 to process the RGB image data.

When the former signal is inputted into the raster image-generating unit 70, the original image data (i.e., PDL data) obtained in Step 100 is converted into a raster image data by the raster image-generating unit 70.

Upon receipt of the latter signal, the color-converting unit 71 converts the image data regarding the RGB color space provided by the raster image-generating unit 70 and serving as the raster image data into an image data regarding the L*a*b* color space which image data does not depend on the types of devices and converts the image data regarding the L*a*b* color space into an image data regarding the YMCK color space.

In the next Step 104, the controller 46 outputs a signal to instruct the picture region/character region judgment unit 72 to distinguish character and picture regions.

Upon receipt of the signal, the picture region/character region judgment unit 72 distinguishes a picture region or regions such as a graphic or a photograph and a character region or regions including at least one character in the image data regarding the L*a*b* color space generated by the color conversion in Step 102.

In the next Step 106, the controller 46 outputs a signal (i.e., selection instruction signal) into instruct the glossing region-selecting unit 73 to select at least one glossing region.

Upon receipt of the selection instruction signal, the glossing region-selecting unit 73 selects at least one glossing region on the basis of the picture and character regions distinguished in Step 104 and at least one type of region that is indicated by the image-type information stored in the memory unit 73A.

More specifically, the glossing region-selecting unit 73 selects a region touching and surrounding each of at least one picture region distinguished in Step 104 as a glossing region on the basis of the image-type information stored in the memory unit 73A and indicating a picture region.

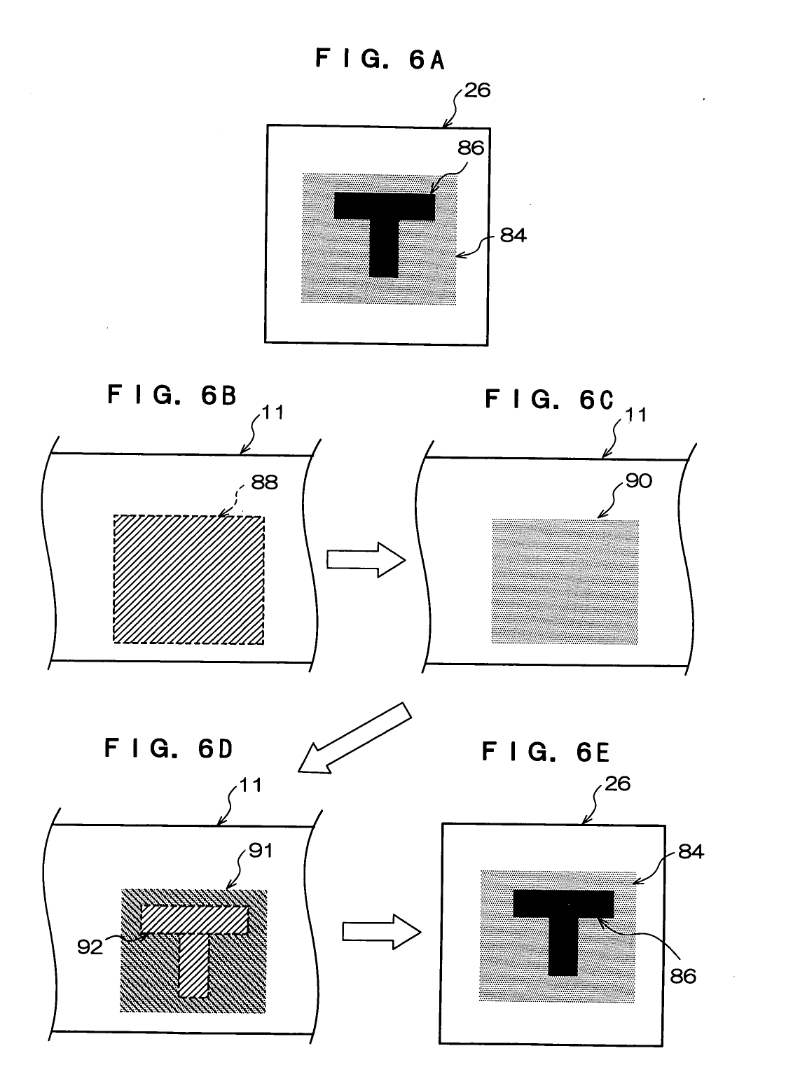

For example, when an image 86 is formed on a recording material 26 (see FIG. 6A), a region touching and surrounding the image 86 is selected as a glossing region (glossing region 84).

The glossing region 84 has a rectangular shape, excluding the image 86, that surrounds the image 86 serving as a picture region in FIG. 6A, but the glossing region 84 is not limited to such a shape. For example, the glossing region 84 may have a shape similar to the outline of the image 86 serving as a picture region.

The shape of the glossing region 84 may be inputted by a user via the input unit 30, and, together with the image-type information, may be stored as shape information in the memory unit 73A. When the selection instruction signal from the controller 46 is inputted at Step 106 in such a case, the glossing region-selecting unit 73 may select, as at least one glossing region, a region or regions touching and surrounding a region or regions each of which is identified as a picture region indicated by the image-type information stored in the memory unit 48, and having a shape the same as the shape indicated by the shape information.

Here, a region touching and surrounding a picture region such as a photograph or a graphic is preferably glossed to reduce differences in surface roughness and gloss between a recording material and an image formed on the recording material.

In the next Step 107, a glossing region data to make the color of a region of the toner image which region corresponds to the glossing region selected in Step 106 colorless is generated for each of the pixels of the glossing region. The glossing region data has a Y color component information data, an M color component information data and a C color component information data. In the glossing region data, the position of each of pixels in the glossing region is correlated with the color of the corresponding pixel, namely, colorlessness.

In the next Step 108, the controller 46 generates a composite image data by adding the glossing region data to the image data regarding the YMCK color space obtained in Step 102.

In the next Step 109, the controller 46 outputs an instruction signal to instruct the definition-processing unit 74 to execute definition processing and an instruction signal to instruct the output gradation-correcting unit 75 to execute output gradation correction.

Upon receipt of the former instruction signal, the definition-processing unit 74 subjects the composite image data generated in Step 108 to processing to smoothen or emphasize the image.

Upon receipt of the latter instruction signal, the output gradation-correcting unit 75 performs nonlinear gamma conversion, which is optimized according to output characteristics of an image such as a dot shape or the kind of a sheet of paper, for each of the color signals of the image data subjected to the above processing in the definition-processing unit 74.

In the next Step 110, the controller 46 instructs the memory unit 48 to store the image data processed in Step 109. If the image data are those of plural pages, the data is stored as pieces of data each of which pieces corresponds to one page.

Each of the pieces of the image data stored in the memory unit 48 is read out in the next Step 112, and the controller 46 outputs signals demanding formation of an electrostatic latent image corresponding to an image that corresponds to the read image data to the image-processing unit 40 and the electrostatic latent image forming unit 14 in the next Step 114.

The image-processing unit 40 outputs the respective color image-forming information data of the processed composite data to the logical sum-processing unit 42. The logical sum-processing unit 42 outputs logical sum data for each pixel to the electrostatic latent image forming unit 14 on the basis of the above data.

The electrostatic latent image forming unit 14 forms an electrostatic latent image according to the inputted logical sum data at timing controlled by the controller 46.

As described above, the image data inputted to the logical sum-processing unit 42 include the image data regarding the YMCK color space obtained in Step 102 and the glossing region data indicating a region touching and surrounding the picture region included in an image corresponding to the image data regarding YMCK color space.

Accordingly, when the electrostatic latent image forming unit 14 irradiates the photoreceptor 11 with light modulated based on the logical sum, an electrostatic latent image including that corresponding to the image corresponding to the image data regarding YMCK color space obtained in Step 102 and that corresponding to the glossing region(s) is formed on the photoreceptor 11.

For example, when an image data to form an image 86 on a recording material 26 is acquired in Step 100 and a region touching and surrounding the image 86 is selected as a glossing region 84 in Step 106, an electrostatic latent image 88 shown in FIG. 6B and including an electrostatic latent image corresponding to the glossing region 84 and that corresponding to the image 86 is formed on the photoreceptor 11 in Step 114.

With rotation of the photoreceptor 11 (in the direction indicated by arrow A in FIG. 1), the electrostatic latent image 88 formed on the photoreceptor 11 reaches a development zone where the photoreceptor 11 faces the toner image forming unit 16. In the development zone, an F toner is adhered to the electrostatic latent image 88. Thus, a toner image 90 corresponding to the electrostatic latent image 88 is formed on the photoreceptor 11, as shown in FIG. 6C.

In the next Step 116, the image data read in Step 112 is outputted via the color forming controller 44 to the color forming information applying unit 28, and a signal demanding application of color forming information and non-color forming information is outputted to the color forming information applying unit 28.

In the color forming information applying unit 28, the Y-color irradiation unit irradiates the toner image with light having a wavelength to enable or inhibit formation of a yellow color according to the Y color component information data, and the M-color irradiation unit irradiates the toner image with light having a wavelength to enable or inhibit formation of a magenta color according to the M color component information data, and the C-color irradiation unit irradiates the toner image with light having a wavelength to enable or inhibit formation of a cyan color according to the C color component information data in Step 114.

When the F toner is an optical color-forming toner, the irradiated portion of the toner image can form a color or colors corresponding to the wavelength or wavelengths of the irradiated light. In this case, the glossing region is not irradiated at all and cannot form a color, and remains its inherent color or colorless even after heating. When the F toner is a non-optical color-forming toner, the irradiated portion of the toner image cannot form a color or colors corresponding to the wavelength(s) of the irradiated light. In this case, the non-irradiated portion of the toner image can form yellow, magenta and cyan colors. Moreover, the irradiated portion cannot form a color or colors corresponding to the wavelength or wavelengths of the irradiated light. In addition, the glossing region is irradiated with light having wavelengths to inhibit formation of yellow, magenta and cyan colors and cannot form a color, and remains its inherent color or colorless even after heating.

For example, when the image 86 in FIG. 6A is cyan, and the F toner is an optical color-forming toner, the region of the toner image 90 (see FIG. 6C) which region corresponds to the image 86 is irradiated with light having a wavelength to allow formation of a cyan color, and can form a cyan color. The other region of the toner image 90 which region corresponds to a glossing region 91 (see FIG. 6D) is not irradiated with light at all and cannot form any color and remains its inherent color or colorless even after heating. Meanwhile, when the image 86 in FIG. 6A is cyan, and the F toner is a non-optical color-forming toner, the region of the toner image 90 which region corresponds to the image 86 is irradiated with light having wavelengths to inhibit formation of yellow and magenta colors, and can form a cyan color. The other region of the toner image 90 which region corresponds to the glossing region 91 is irradiated with light having wavelengths to inhibit formation of yellow, magenta and cyan colors, and cannot form any color and remains its inherent color or colorless even after heating.

More specifically, when the F toner contained in the toner image forming unit 16 of the image-forming device 10 of the exemplary embodiment is an optical color-forming toner, and can form a yellow color when irradiated with light having a wavelength of 405 nm, and can form a magenta color when irradiated with light having a wavelength of 535 nm, and can form a cyan color when irradiated with light having a wavelength of 657 nm as described previously, a glossing region is not irradiated with light having wavelengths of 405 nm, 535 nm, and 657 nm.

Meanwhile, the region corresponding to the image 86 is irradiated with light having a wavelength of 657 nm, and is not irradiated with light having wavelengths of 405 nm and 535 nm.

On the other hand, when the F toner contained in the toner image forming unit 16 of the image-forming device 10 of the exemplary embodiment is a non-optical color-forming toner, and cannot form a yellow color when irradiated with light having a wavelength of 405 nm, and cannot form a magenta color when irradiated with light having a wavelength of 535 nm, and cannot form a cyan color when irradiated with light having a wavelength of 657 nm as described previously, a glossing region is irradiated with light having wavelengths of 405 nm, 535 nm, and 657 nm at maximum light exposures.

Meanwhile, the region corresponding to the image 86 is irradiated with light having wavelengths of 405 nm and 535 nm and is not irradiated with light having a wavelength of 657 nm.

With rotation of the photoreceptor 11, the toner image to which color forming information and non-color forming information have been applied reaches a transfer zone where the photoreceptor 11 faces the transfer unit 18. In the transfer zone, the toner image is transferred onto a recording material 26. The recording material is conveyed and passes through a nip portion of the heated rolls of the fixing unit 22. As a result, the toner image is fixed on the recording material 26 and the color is formed in the toner image. The toner image transferred and developed on the recording material 26 does not form any color of yellow, magenta, and cyan colors in the glossing region selected in Step 106 and remains its inherent color or colorless, which is the color of the F toner that has not been color-formed (see FIG. 6E). Meanwhile, a cyan color has been formed in the picture region included in the original image data obtained in Step 100 to form an image.

In the next Step 118, the controller 46 judges whether processing of all the processed image data stored in the memory unit 48 in Step 110 has been completed. When it is judged that the processing has not been completed, the routine proceeds to Step 120. In this step, the piece of the image data which piece corresponds to the next page is read out as the image data to be processed next. Thereafter, the routine goes back to Step 114. Meanwhile, when it is judged that the processing has been completed in Step 118, the routine ends.

For short, the following is conducted in the image-forming device 10 of the embodiment in which a toner that optically switches from a color-forming state (first state) to a non-color-forming state (second state) or vice versa by application of light is used. First, an original image data is acquired, and it is judged whether the original image data include at least one picture region. When the original image data include at least one picture region, the glossing region-selecting unit 73 determines at least one glossing region corresponding to the at least one picture region. Here, one glossing region may be selected for the at least one picture region or for the corresponding one of the at least one picture region. Thereafter, an electrostatic latent image including a region corresponding to the original image data and a region corresponding to the at least one glossing region is formed on a photoreceptor. Next, the toner is adhered to the electrostatic latent image.

Subsequently, light serving as color forming information or non-color forming information to switch the toner form a color-forming state to a non-color-forming state or vice versa is applied to the toner image so that an image corresponding to the original image data can be formed in a region other than the glossing region and so that no color can be formed in the glossing region. The toner image is transferred onto a recording material before or after the application of the color forming information and the non-color forming information. The toner image to which the color forming information and the non-color forming information have been given and that has been transferred onto the recording material is heated by a fixing unit 22. As a result, a desired color or colors are formed in the region corresponding to the original image data, and the at least one glossing region of the toner image is glossed by heating the toner that is in a non-color-forming state.

Accordingly, the image-forming device can gloss only the selected glossing region(s) of the toner image transferred onto the recording material 26, regardless of a simple configuration without a complicated unit for glossing.

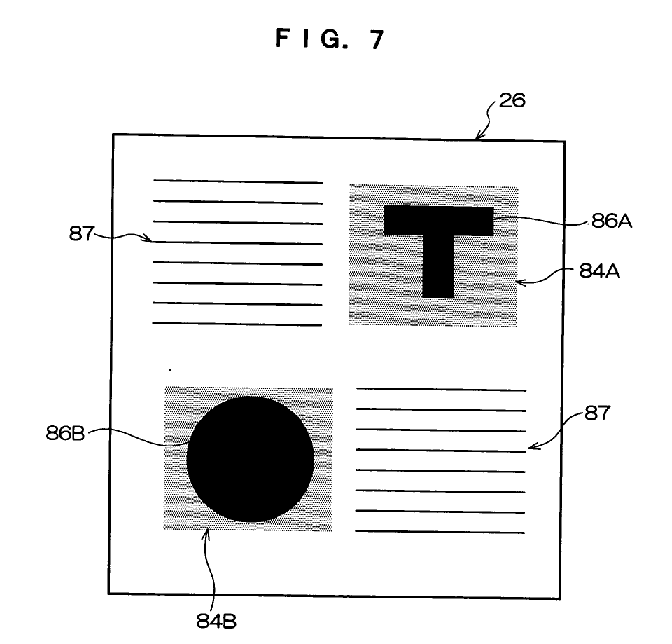

As shown in FIG. 7, decrease in readability of characters which decrease is caused by glossing character regions 87 and a difference in surface roughness between picture regions and the recording material 26 can be prevented by executing the aforementioned routine. This is because the device can be so controlled as to gloss glossing regions 84A and 84B that respectively touches and surrounds picture regions 86A and 86B such as a photograph or a graphic and as not to gloss the character region 87 having characters.

In the exemplary embodiment, the density in the glossing region is constant. However, the degree of gloss in the glossing region may be altered according to the density of the picture region to which the glossing region corresponds.

For example, the amount of the toner supplied to the glossing region is so adjusted that, as the density of the picture region increases, the degree of the gloss of the glossing region increases, in Step 106 where the glossing region is selected. In this case, the electrostatic latent image forming unit 14 needs to emit light at various light exposures, and a glossing region surrounding a picture region with a high density is irradiated with light at a high intensity (light exposure) in forming an electrostatic latent image.

In the exemplary embodiment, the glossing region is kept colorless or its inherent color. However, when the F toner further has a color-forming portion that can form a white color, the glossing region may become white by heating. This is useful when the color of a recording material is not white.

In this case, the color forming information applying unit further has a light source that emit light having a wavelength to change the glossing region from a non-color-forming state to a white color-forming state, and the light sources 53Y, 53M and 53C do not irradiate the glossing region. Moreover, the image-forming device can be configured such that the color of the glossing region after heating can be selected from white and colorless in that case.

In the invention, it is possible to generate difference in gloss in a desired region. In this case, a transparency character or picture can be formed by using the difference in gloss.

When an image corresponding to the original image data includes two or more picture regions in the invention, the absence (non-formation) of a glossing region with respect to at least one of the two or more picture regions may be selected.

### EXPERIMENTAL EXAMPLE

The following experiments are performed to confirm the advantageous effects of the above exemplary embodiment.

The “part” and “%” in the following Examples respectively represent “parts by mass” and “% by mass”.

### Preparation of Toner

Toners used in the following Examples will be described first. In preparation of the following toners, photocurable composition dispersion liquids and toners using the same are prepared in a dark place.

### A. Non-Optical Color-Forming Toner

### Preparation of Microcapsule Dispersion Liquid

### —Microcapsule Dispersion Liquid (1)—

8.9 parts by mass of a yellow color-forming electron-donating colorless dye (1) is dissolved in 16.9 parts by mass of ethyl acetate. Twenty parts by mass of a capsule wall-forming material (TAKENATE D-110N manufactured by Takeda Pharmaceutical Company Limited.) and 2 parts by mass of another capsule wall-forming material (MILLIONATE MR200 manufactured by Nippon Polyurethane Industry Co., Ltd.) are added to the resultant solution.

The resulting mixture is added to a liquid mixture containing 42 parts by mass of 8 mass % phthalated gelatin, 14 parts by mass of water, and 1.4 parts by mass of 10 mass % sodium dodecylbenzenesulfonate solution, and the obtained admixture is stirred at temperature 20° C. to form an emulsion-dispersion liquid. Then, 72 parts by mass of 2.9 mass % aqueous tetraethylenepentamine solution is added to the emulsion-dispersion liquid. The resultant mixture, which is being stirred, is heated to 60° C. and kept at that temperature for 2 hours. Thus, a microcapsule dispersion liquid (1) that contains microcapsules having an average particle diameter of 0.5 μm and containing the electron-donating colorless dye (1) as its core material is obtained.

The glass transition temperature of the material of the shells of the microcapsules contained in the microcapsule dispersion liquid (1) (material obtained by reacting TAKENATE D-110N and MILLIONATE MR200 under conditions similar to the above) is 100° C.

### —Microcapsule Dispersion Liquid (2)—

A microcapsule dispersion liquid (2) is prepared in the same manner as the microcapsule dispersion liquid (1), except that the electron-donating colorless dye (1) is replaced with an electron-donating colorless dye (2). The average particle diameter of the microcapsules in the microcapsule dispersion liquid (2) is 0.5 μm.

### —Microcapsule Dispersion Liquid (3)—

A microcapsule dispersion liquid (3) is prepared in the same manner as the microcapsule dispersion liquid (1), except that the electron-donating colorless dye (1) is replaced with an electron-donating colorless dye (3). The average particle diameter of the microcapsules in the microcapsule dispersion liquid (2) is 0.5 μm.

The Chemical Formulae of the electron-donating colorless dyes (1) to (3) used in the preparation of the microcapsule dispersion liquids are shown below.

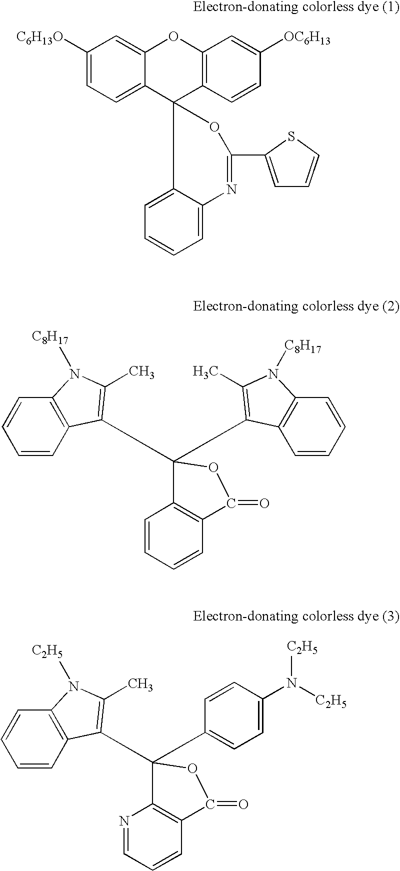

### Preparation of Photocurable Composition Dispersion Liquid

### —Photocurable Composition Dispersion Liquid (1)—

100.0 parts by mass of a mixture of polymerizable group-containing electron-accepting compounds (1) and (2) (blending ratio of 50:50) and 0.1 parts by mass of a thermal polymerization inhibitor (ALI) are dissolved in 125.0 parts by mass of isopropyl acetate (having a solubility of approximately 4.3% in water) at 42° C. to prepare a mixed solution I.

18.0 parts by mass of hexaarylbiimidazole (1) [2,2′-bis(2-chlorophenyl)-4,4′,5,5′-tetraphenyl-1,2′-biimidazole], 0.5 parts by mass of a nonionic organic dye, and 6.0 parts by mass of an organic boron compound are added to the mixed solution I and dissolved therein at 42° C. to prepare a mixed solution II.

The mixed solution II is added to a mixed solution of 300.1 parts by mass of 8 mass % aqueous gelatin solution and 17.4 parts by mass of 10 mass % aqueous surfactant (1) solution, and emulsified therein with a homogenizer (manufactured by Nippon Seiki Co., Ltd.) at 10,000 rpm for 5 minutes. The solvent is then removed from the resultant emulsion at 40° C. for 3 hours to prepare a photocurable composition dispersion liquid (1) having a solid content of 30 mass %.

The structural formulae of the polymerizable group-containing electron-accepting compound (1), the polymerizable group-containing electron-accepting compound (2), the thermal polymerization inhibitor (ALI), hexaarylbiimidazole (1), the surfactant (1), the nonionic organic dye, and the organic boron compound used in the preparation of the photocurable composition dispersion liquid (1) are shown below.

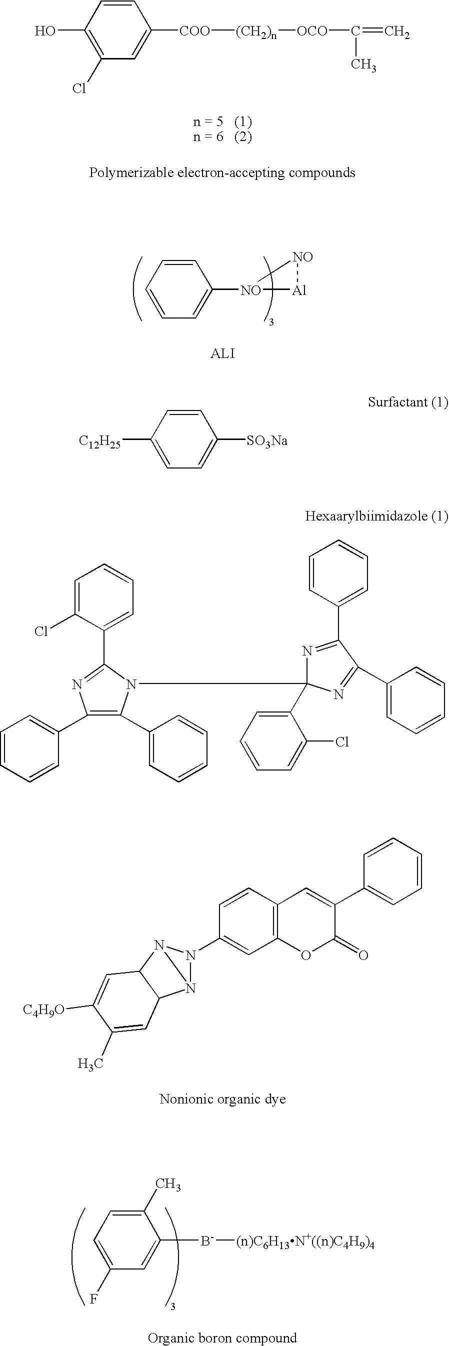

### —Photocurable Composition Dispersion Liquid (2)—

Five parts by mass of the following electron-accepting compound (3) having at least one polymerizable group is added to a mixed solution containing 0.6 parts by mass of the following organic borate compound (I), 0.1 parts by mass of the following spectral sensitizing dye borate compound (I), 0.1 parts by mass of the following assistant (1) for improving sensitivity, and 3 parts by mass of isopropyl acetate (solubility of approximately 4.3% in water).

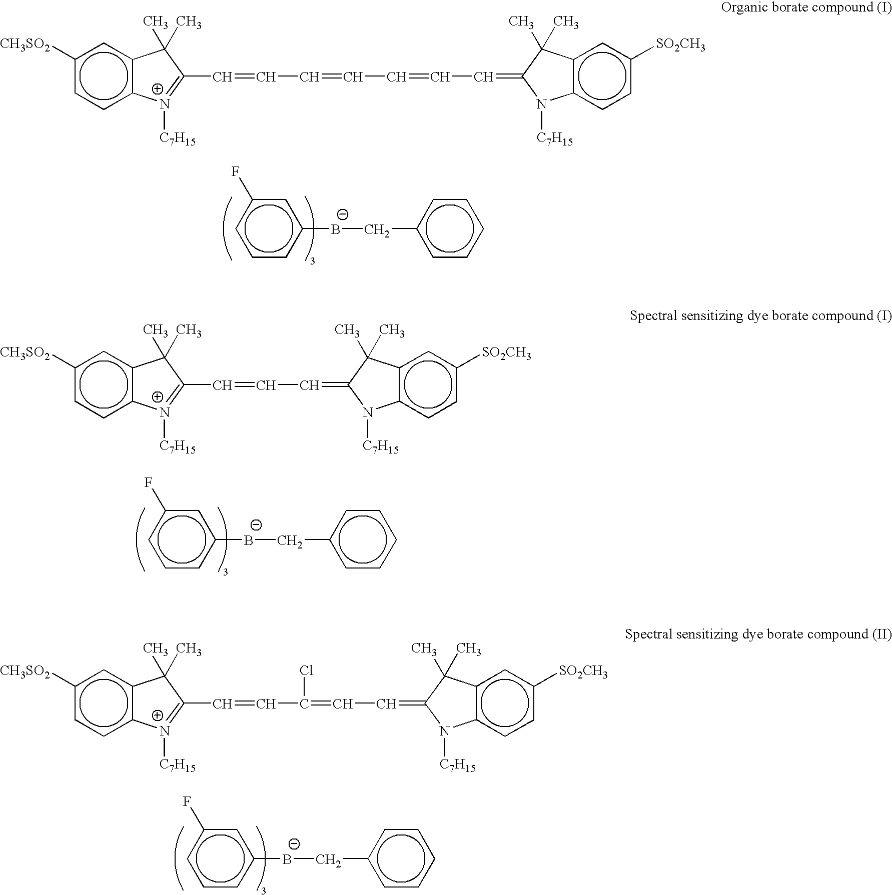

The solution obtained is added to a mixed solution of 13 parts by mass of 13 mass % aqueous gelatin solution, 0.8 parts by mass of a 2 mass % aqueous solution of the following surfactant (2), and 0.8 parts by mass of a 2 mass % aqueous solution of the following surfactant (3). The resultant mixture is stirred with a homogenizer (manufactured by Nippon Seiki Co., Ltd.) at 10,000 rpm to prepare a photocurable composition dispersion liquid (2).

The structural formulae of the polymerizable group-containing electron-accepting compound (3), the assistant (1), the surfactant (2), and the surfactant (3) used in the preparation of the photocurable composition dispersion liquid (2) are shown below.

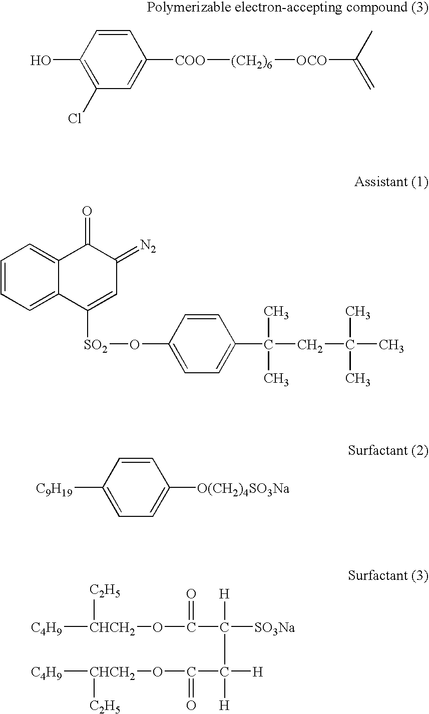

### —Photocurable Composition Dispersion Liquid (3)—

A photocurable composition dispersion liquid (3) is prepared in the same manner as the photocurable composition dispersion liquid (2), except that the spectral sensitizing dye borate compound (I) is replaced with 0.1 parts by mass of the spectral sensitizing dye borate compound (II).

### Preparation of Resin Particle Dispersion Liquid

Styrene 460 parts by mass
n-Butyl acrylate 140 parts by mass
Acrylic acid 12 parts by mass
Dodecanethiol 9 parts by mass

These components are sufficiently mixed to prepare a solution. The solution is added to another solution obtained by dissolving 12 parts by mass of an anionic surfactant (DOW-FAX manufactured by Rhodia) in 250 parts by mass of deionized water in a polymerization flask and the resultant is stirred to prepare an emulsion-dispersion liquid (monomer emulsion A).

A solution obtained by dissolving one part by mass of the anionic surfactant (DOW-FAX manufactured by Rhodia) in 555 parts by mass of deionized water is placed in the polymerization flask. The polymerization flask is sealed tightly and a reflux condenser is joined to the polymerization flask. The resultant mixture, which is being slowly stirred and to which nitrogen gas is being introduced, is heated to 75° C. and kept at that temperature by putting the polymerization flask in a water bath.

Then, a solution obtained by dissolving 9 parts by mass of ammonium persulfate in 43 parts by mass of deionized water is dripped into the polymerization flask by a metering pump over 20 minutes. Thereafter, the monomer emulsion A is dripped into the polymerization flask by a metering pump over 200 minutes.

While the resultant mixture is agitated slowly, the polymerization flask is kept at 75° C. for 3 hours to complete polymerization.

Thus, a resin particle dispersion liquid that contains particles having a median diameter of 210 nm, a glass transition point of 51.5° C., and a weight-average molecular weight of 31,000 and that has a solid content of 42% is obtained.

### Preparation of Toner 1 (Color-Forming Region-Dispersed Toner)

### —Preparation of Photosensitive and Thermosensitive Capsule Dispersion Liquid (1)—

Microcapsule dispersion liquid (1) 150 parts by mass
Photocurable composition dispersion liquid (1) 300 parts by mass
Polyaluminum chloride 0.20 parts by mass
Deionized water 300 parts by mass

These components are mixed to prepare a raw material solution. Nitric acid is added to the raw material solution to adjust the pH of the solution at 3.5. The solution is stirred sufficiently with a homogenizer (ULTRA TURRAX T50 manufactured by IKA company), and transferred into a flask. The solution is heated to 40° C. in an oil bath and kept at 40° C. for 60 minutes, while stirred with THREE-ONE MOTOR. Three hundred parts by mass of the resin particle dispersion liquid is added to the content of the flask, and the resultant mixture is stirred gently at 60° C. for 2 hours to prepare a photosensitive and thermosensitive capsule dispersion liquid (1).

The volume-average particle diameter of the photosensitive and thermosensitive capsules dispersed in the dispersion liquid is 3.53 μm. There is no spontaneous color forming of the dispersion liquid during the preparation of the dispersion liquid.

### —Preparation of Photosensitive and Thermosensitive Capsule Dispersion Liquid (2)—

Microcapsule dispersion liquid (2) 150 parts by mass
Photocurable composition dispersion liquid (2) 300 parts by mass
Polyaluminum chloride 0.20 parts by mass
Deionized water 300 parts by mass

A photosensitive and thermosensitive capsule dispersion liquid (2) is prepared in the same manner as the photosensitive and thermosensitive capsule dispersion liquid (1), except that the raw material solution is replaced with another raw material solution including the above components.

The volume-average particle diameter of the photosensitive and thermosensitive capsules dispersed in the dispersion liquid is 3.52 μm. There is no spontaneous color forming of the dispersion liquid during the preparation of the dispersion liquid.

### —Preparation of Photosensitive and Thermosensitive Capsule Dispersion Liquid (3)—

Microcapsule dispersion liquid (3) 150 parts by mass
Photocurable composition dispersion liquid (3) 300 parts by mass
Polyaluminum chloride 0.20 parts by mass
Deionized water 300 parts by mass

A photosensitive and thermosensitive capsule dispersion liquid (3) is prepared in the same manner as the photosensitive and thermosensitive capsule dispersion liquid (1), except that the raw material solution is replaced with another raw material solution including the above components.

The volume-average particle diameter of the photosensitive and thermosensitive capsules dispersed in the dispersion liquid is 3.47 μm. There is no spontaneous color forming of the dispersion liquid during the preparation of the dispersion liquid.

### —Preparation of Toner—

Photosensitive and thermosensitive capsule dispersion liquid (1) 750 parts by mass
Photosensitive and thermosensitive capsule dispersion liquid (2) 750 parts by mass
Photosensitive and thermosensitive capsule dispersion liquid (3) 750 parts by mass

A solution containing the above components is placed in a flask. The solution, which is being stirred, is heated to 42° C. and kept at 42° C. for 60 minutes in an oil bath. Hundred parts by mass of the resin particle dispersion liquid is added to the solution, and the resultant mixture is stirred gently.

Then, 0.5 mole/liter aqueous sodium hydroxide solution is added to the solution to adjust the pH of the solution at 5.0 . Thereafter, the solution, which is being stirred, is heated to 55° C. When the temperature of the solution is being raised to 55° C., the pH of the content in the flask decreases to 5.0 or less. However, the aqueous sodium hydroxide solution is additionally dripped into the solution to keep the pH of the solution at a value of more than 4.5. The mixture is kept at 55° C. for 3 hours in this state.

After completion of reaction, the mixture is cooled down, and filtered. The resultant solid is washed thoroughly with deionized water, and the resulting dispersion liquid is filtered with a Nuche suction filter to divide the dispersion liquid into liquid and solid. The solid is dispersed in 3 liters of deionized water that is contained in a 5-liter beaker and that is kept at 40° C., and the resultant dispersion is stirred at 300 rpm for 15 minutes to wash the solid. Thereafter, the dispersion is divided into liquid and solid. The washing and division operations are repeated four times. Thereafter, the washing operation is conducted once more, and the resulting dispersion liquid is filtered with the Nuche suction filter to divide the dispersion into liquid and solid. The solid is freeze-vacuum-dried for 12 hours to obtain toner mother particles in which the photosensitive and thermosensitive capsules are dispersed in a styrene resin. The volume-average particle diameter D50v of the toner mother particles is measured by using Coulter Counter, and found to be 15.2 μm. 1.0 part by mass of hydrophobic silica (TS720 manufactured by Cabot) is added to 50 parts by mass of the toner mother particles, and the resultant mixture is stirred with a sample mill to prepare toner 1 (toner to which an external additive has adhered).

### Preparation of Toner 2 (Having a Concentric Circular Structure))

### —Preparation of Toner—

Microcapsule dispersion liquid (1) 150 parts by mass
Photocurable composition dispersion liquid (1) 300 parts by mass
Polyaluminum chloride 0.20 parts by mass
Deionized water 300 parts by mass

These components are mixed to prepare a solution. Nitric acid is added to the solution to adjust the pH of the solution at 3.5. The solution is stirred sufficiently with a homogenizer (ULTRA TURRAX T50 manufactured by IKA company), and transferred into a flask. The solution is heated to 40° C. in an oil bath and kept at 40° C. for 60 minutes, while stirred with THREE-ONE MOTOR. Three hundred parts by mass of the resin particle dispersion liquid is added to the content of the flask, and the resultant mixture is stirred gently.

0.5 mole/liter aqueous sodium hydroxide solution is added to the mixture to adjust the pH of the mixture at 7.5. The mixture, which is being gently stirred, is heated to 60° C. and kept at 60° C. for 2 hours. The resultant reaction system is taken out of the flask, left and cooled down to obtain a photosensitive and thermosensitive capsule dispersion liquid.

The volume-average particle diameter of the photosensitive and thermosensitive capsules dispersed in the dispersion liquid is 4.50 μm. There is no spontaneous color forming of the dispersion liquid during the preparation of the dispersion liquid.

A mixed solution of the following components is added to the photosensitive and thermosensitive capsule dispersion liquid. Nitric acid is added to the resultant mixture to adjust the pH of the mixture at 3.5, and the mixture is stirred sufficiently with a homogenizer (ULTRA TURRAX 50 manufactured by IKA company).
Microcapsule dispersion liquid (2) 150 parts by mass
Photocurable composition dispersion liquid (2) 300 parts by mass
Polyaluminum chloride 0.20 parts by mass
Deionized water 300 parts by mass

The sufficiently stirred solution is transferred into a flask. The solution is heated to 40° C. in an oil bath and kept at 40° C. for 60 minutes, while stirred with THREE-ONE MOTOR. Two hundred parts by mass of the resin particle dispersion liquid is added to the content of the flask, and the resultant mixture is stirred gently.

0.5 mole/liter aqueous sodium hydroxide solution is added to the mixture to adjust the pH of the mixture at 7.5. The mixture, which is being gently stirred, is heated to 60° C. and kept at 60° C. for 2 hours. The resultant reaction system is taken out of the flask, left and cooled down to obtain a photosensitive and thermosensitive capsule dispersion liquid.

The volume-average particle diameter of the photosensitive and thermosensitive capsules dispersed in the dispersion liquid is 6.0 μm. There is no spontaneous color forming of the dispersion liquid during the preparation of the dispersion liquid.

A mixed solution of the following components is added to the photosensitive and thermosensitive capsule dispersion liquid. Nitric acid is added to the resultant mixture to adjust the pH of the mixture at 3.5, and the mixture is stirred sufficiently with a homogenizer (ULTRA TURRAX 50 manufactured by IKA company).
Microcapsule dispersion liquid (3) 150 parts by mass
Photocurable composition dispersion liquid (3) 300 parts by mass
Polyaluminum chloride 0.20 parts by mass
Deionized water 300 parts by mass

The sufficiently stirred solution is transferred into a flask. The solution is heated to 40° C. in an oil bath and kept at 40° C. for 60 minutes, while stirred with THREE-ONE MOTOR. One hundred parts by mass of the resin particle dispersion liquid is added to the content of the flask, and the resultant mixture is stirred gently at 60° C. for two hours.

0.5 mole/liter aqueous sodium hydroxide solution is added to the mixture to adjust the pH of the mixture at 5.0. The mixture, which is being gently stirred, is heated to 55° C. and kept at 60° C. for 2 hours. When the temperature of the solution is being raised to 55° C., the pH of the content in the flask decreases to 5.0 or less. However, the aqueous sodium hydroxide solution is additionally dripped to the solution to keep the pH of the solution at a value of more than 4.5. The mixture is kept at 55° C. for 3 hours in this state to prepare a dispersion liquid. There is no spontaneous color forming of the dispersion liquid during the preparation of the dispersion liquid.

After completion of reaction, the dispersion liquid is cooled down, and filtered. The resultant solid is washed thoroughly with deionized water, and the resulting dispersion liquid is filtered with a Nuche suction filter to divide the dispersion liquid into liquid and solid. The solid is dispersed in 3 liters of deionized water that is contained in a 5-liter beaker and that is kept at 40° C., and the resultant dispersion is stirred at 300 rpm for 15 minutes to wash the solid. Thereafter, the dispersion is divided into liquid and solid. The washing and division operations are repeated four times. Thereafter, the washing operation is conducted once more, and the resulting dispersion liquid is filtered with the Nuche suction filter to divide the dispersion into liquid and solid. The solid is freeze-vacuum-dried for 12 hours to obtain toner mother particles.

The volume-average particle diameter D50v of the toner mother particles is measured by using Coulter Counter, and found to be 7.5 μm. 1.0 part by mass of hydrophobic silica (TS720 manufactured by Cabot) is added to 50 parts by mass of the toner mother particles, and the resultant mixture is stirred with a sample mill to prepare toner 2 (toner to which an external additive has adhered).

### B. Optical Color-Forming Toner

### Preparation of Microcapsule Dispersion Liquid

### —Microcapsule Dispersion Liquid (1)—

12.1 parts by mass of the electron-donating colorless dye (1) is dissolved in 10.2 parts by mass of ethyl acetate. 12.1 parts by mass of dicyclohexyl phthalate, 26 parts by mass of TAKENATE D-110N (manufactured by Takeda Pharmaceutical Company Limited.), and 2.9 parts by mass of MILLIONATE MR200 (manufactured by Nippon Polyurethane Industry Co., Ltd.) are added to the resultant solution.

The resulting solution is then added to a liquid mixture of 5.5 parts by mass of polyvinyl alcohol and 73 parts by mass of water. The blend obtains is stirred at 20° C. to prepare an emulsion-dispersion liquid containing particles with an average particle diameter of 0.5 μm. Eighty parts by mass of water is added to the emulsion-dispersion liquid. The resultant mixture, which is being stirred, is heated to 60° C. and kept at that time for two hours. Thus, a microcapsule dispersion liquid (1) in which microcapsules including the electron-donating colorless dye (1) as its core material are dispersed is obtained.

The glass transition temperature of the material of the shells of the microcapsules contained in the microcapsule dispersion liquid (1) (product obtained by reacting dicyclohexyl phthalate, TAKENATE D-110N and MILLIONATE MR200 under conditions similar to the above) is 130° C.

### —Microcapsule Dispersion Liquid (2)—

A microcapsule dispersion liquid (2) is prepared in the same manner as the microcapsule dispersion liquid (1), except that the electron-donating colorless dye (1) is replaced with the electron-donating colorless dye (2).

### —Microcapsule Dispersion Liquid (3)—

A microcapsule dispersion liquid (3) is prepared in the same manner as the microcapsule dispersion liquid (1), except that the electron-donating colorless dye (1) is replaced with the electron-donating colorless dye (3).

### Preparation of Photocurable Composition Dispersion Liquid

### —Photocurable Composition Dispersion Liquid (1)—

Nine parts of the electron-accepting compound (1) and 7.5 parts of a trimethylolpropane triacrylate monomer (trifunctional acrylate having molecular weight of approximately 300) are added to a solution obtained by dissolving 1.62 parts of a photopolymerization initiator (1-a) and 0.54 parts of a photopolymerization initiator (1-b) in 4 parts of ethyl acetate.

The resultant mixture is added to a mixed solution of 19 parts of 15% aqueous PVA (polyvinyl alcohol) solution, 5 parts of water, 0.8 parts of 2% aqueous solution of a surfactant (1), and 0.8 parts of 2% aqueous solution of a surfactant (2). The resultant blend is stirred with a homogenizer (manufactured by Nippon Seiki Co., Ltd.) at 8,000 rpm for 7 minutes to prepare a photocurable composition dispersion liquid (emulsion) (1).

### —Photocurable Composition Dispersion Liquid (2)—

A photocurable composition dispersion liquid (2) is prepared in the same manner as the photocurable composition dispersion liquid (1), except that the photopolymerization initiators (1-a) and (1-b) are replaced with 0.08 parts of a photopolymerization initiator (2-a), 0.18 parts of a photopolymerization initiator (2-b), and 0.18 parts of a photopolymerization initiator (2-c).

### —Photocurable Composition Dispersion Liquid (3)—

A photocurable composition dispersion liquid (3) is prepared in the same manner as the photocurable composition dispersion liquid (2), except that the photopolymerization initiator (2-b) is replaced with a photopolymerization initiator (3-b).

The Chemical Formulae of the photopolymerization initiators (1-a), (1-b), (2-a), (2-b), (2-c), and (3-b), the electron-accepting compound (1), and the surfactants (1) and (2) used in the preparation of the photocurable composition dispersion liquid are shown below.

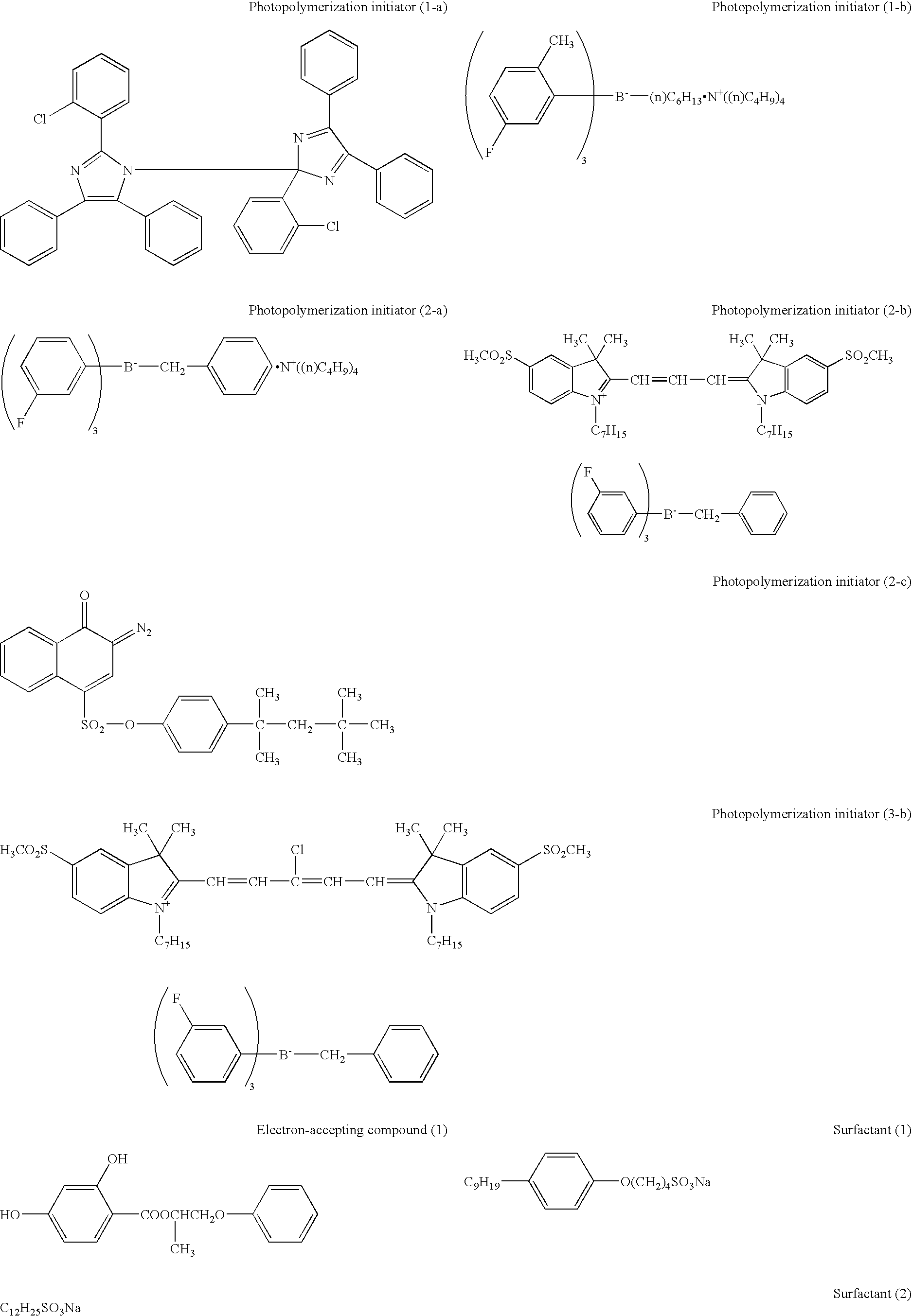

### —Preparation of Resin Particle Dispersion Liquid (1)—

Styrene 360 parts
n-Butyl acrylate 40parts
Acrylic acid 4 parts
Dodecanethiol 24 parts
Carbon tetrabromide 4 parts

A solution of the above components is dispersed and emulsified in a mixed solution obtained by dissolving 6 parts of a nonionic surfactant (NONIPOL 400 manufactured by Sanyo Chemical Industries Co., Ltd.) and 10 parts of an anionic surfactant (NEOGEN SC manufactured by Dai-ichi Kogyo Seiyaku Co., Ltd.) in 560 parts of deionized water in a flask. While the resultant mixture is agitated gently for 10 minutes, a solution obtained by dissolving 4 parts of ammonium persulfate in 50 parts of deionized water is added to the mixture.

Subsequently, the air in the flask is substituted with nitrogen. The resultant admixture, which is being stirred, is heated to 70° C. in an oil bath and kept at that temperature for 5 hours to conduct emulsion polymerization. Thus, a resin particle dispersion liquid (1) in which resin particles having a volume-average particle diameter of 200 nm, a glass transition temperature of 50° C., a weight-average molecular weight (Mw) of 16,200, and a specific gravity of 1.2 (resin particle concentration of 30%) are dispersed is obtained.

### —Preparation of Photosensitive and Thermosensitive Capsule Dispersion Liquid (1)—

Microcapsule dispersion liquid (1) 24 parts
Photocurable composition dispersion liquid (1) 232 parts

The above components are sufficiently mixed and stirred in a round bottom stainless steel flask with ULTRA TURRAX T50 manufactured by IKA company.

Nitric acid is added to the resultant mixture to adjust the pH of the mixture at 3, and 0.20 parts of polyaluminum chloride is added to the mixture. The resulting admixture is stirred with ULTRA TURRAX at 6,000 rpm for 10 minutes. The admixture, which is being slowly stirred, is heated to 40° C. in an oil bath.

Sixty parts of the resin particle dispersion liquid (1) is added gently to the admixture.

Thus, a photosensitive and thermosensitive capsule dispersion liquid (1) is obtained. The volume-average particle diameter of the photosensitive and thermosensitive capsules dispersed in the dispersion liquid is approximately 2 μm. There is no spontaneous color forming of the dispersion liquid.

### —Preparation of Photosensitive and Thermosensitive Capsule Dispersion Liquid (2)—

A photosensitive and thermosensitive capsule dispersion liquid (2) is prepared in the same manner as the photosensitive and thermosensitive capsule dispersion liquid (1), except that the microcapsule dispersion liquid (1) is replaced with the microcapsule dispersion liquid (2) and the photocurable composition dispersion liquid (1) is replaced with the photocurable composition dispersion liquid (2). The volume-average particle diameter of the photosensitive and thermosensitive capsules dispersed in the dispersion liquid is about 2 μm. There is no spontaneous color forming of the dispersion liquid.

### —Preparation of Photosensitive and Thermosensitive Capsule Dispersion Liquid (3)—

A photosensitive and thermosensitive capsule dispersion liquid (3) is prepared in the same manner as the photosensitive and thermosensitive capsule dispersion liquid (1), except that the microcapsule dispersion liquid (1) is replaced with the microcapsule dispersion liquid (3) and the photocurable composition dispersion liquid (1) is replaced with the photocurable composition dispersion liquid (3). The volume-average particle diameter of the photosensitive and thermosensitive capsules dispersed in the dispersion liquid is about 2 μm. There is no spontaneous color forming of the dispersion liquid.

### Preparation of Toner 3 (Color Forming Region-Dispersed Toner)

### —Preparation of Toner—

Photosensitive and thermosensitive capsule dispersion liquid (1) 80 parts
Photosensitive and thermosensitive capsule dispersion liquid (2) 80 parts
Photosensitive and thermosensitive capsule dispersion liquid (3) 80 parts
Resin particle dispersion liquid (1) 80 parts

The above components are mixed and stirred sufficiently in a round bottom stainless steel flask with ULTRA TURRAX T50 manufactured by IKA company.

0.1 parts of polyaluminum chloride is added to the resultant mixture, and the obtained blend is stirred by using ULTRA TURRAX at 6,000 rpm for 10 minutes. The blend, which is being stirred, is heated to 48° C. in an oil bath. The blend is kept at 48° C. for 60minutes, and 20 parts of the resin particle dispersion liquid (1) is added gently thereto.

0.5 mol/l aqueous sodium hydroxide solution is added to the resultant mixture to adjust the pH of the mixture at 8.5. The stainless steel flask is then sealed tightly, and the mixture, which is being stirred by using a magnetic force seal, is heated to 55° C. and kept at that temperature for 10 hours.

After completion of reaction, the reaction system is cooled down, and filtered. The resultant solid is washed sufficiently with deionized water, and the resulting dispersion liquid is filtered with a Nuche suction filter to divide the dispersion liquid into liquid and solid. The solid is dispersed again in one liter of deionized water kept at 40° C., and the resultant dispersion is stirred at 300 rpm for 15 minutes to wash the solid. Thereafter, the dispersion liquid is divided into liquid and solid.

The washing and division operations are repeated four more times. Thereafter, the washing operation is conducted once more. The resultant dispersion liquid has a pH of 7.5 and an electrical conductivity of 7.0 μs/cmt. The dispersion liquid is filtered with the Nuche suction filter in which filter paper No. 5A is set to divide the dispersion liquid into liquid and solid. The solid is vacuum-dried for 12 hours to obtain toner mother particles in which three types of photosensitive and thermosensitive capsules are dispersed in a base material.

The volume-average particle diameter D50v of the toner mother particles is measured by using Coulter Counter, and found to be 15 μm. There is no spontaneous color forming of the dispersion liquid.

One hundred parts of the toner (1), 0.3 parts of hydrophobic titania particles whose surfaces have been treated with n-decyltrimethoxysilane and that have an average particle diameter of 15 nm, and 0.4 parts of hydrophobic silica having an average particle diameter of 30 nm (NY50 manufactured by Nippon Aerosil Co., Ltd.) are blended with a Henschel mixer at a peripheral speed of 32 m/s for 10 minutes. Coarse particles are removed from the resultant blend by using a sieve having a pore size of 45 μm. Thus, a toner 3 (toner to which external additives have adhered) is obtained.

### <Preparation of Developer>

Ferrite carrier particles having an average particle diameter of 50 μm and including cores coated with polymethyl methacrylate (manufactured by Soken Chemical & Engineering) are prepared. The content of polymethyl methacrylate in the carrier particles is 1 mass %. Each of the toners 1 to 3 is mixed with the ferrite carrier particles with a ball mill for 5 minutes. Thus, developers (1) to (3) are prepared. The concentration of the toner in each of the developers is 5 mass %. Each of the developers (1) and (2) contains a non-optical color-forming toner, and the developer (3) contains an optical color-forming toner.

### EXAMPLE 1

### Image Formation

An image-forming device shown in FIG. 1 is provided, and the developer (1) is used in the device.

The photoreceptor 11 of the image-forming device is a product having an aluminum drum and a multilayered organic photosensitive coating film that has a thickness of 25 μm and that has a charge-generating layer including gallium phthalocyanine chloride and a charge transport layer including N,N′-diphenyl-N,N′-bis(3-methylphenyl)-[1,1′]biphenyl-4,4′-diamine. The charging unit 12 of the image-forming device is Scorotron.

The electrostatic latent image forming unit 14 of the image-forming device is an LED image bar that can emit light having a wavelength of 780 nm and capable of forming an electrostatic latent image at a definition of 600 dpi. The toner image forming unit 16 of the image-forming device has a metal sleeve for two-component magnetic brush development and is capable of conducting reversed development. The charged amount of the toner, when the developer 1 is supplied to the toner image formation unit, is approximately −5 to −30 μC/g.

The color forming information applying unit 28 of the image-forming device is an LED image bar that can emit light having peak wavelengths of 405 nm (light exposure of 0.2 mJ/cm³), 532 nm (light exposure of 0.2 mJ/cm²), and 657 nm (light exposure of 0.4 mJ/cm²) and that has a definition of 600 dpi. The transfer unit 18 of the image-forming device has, as a transfer roll, a semi-conductive roll having a conductive elastomer layer formed on the external surface of a conductive core. The conductive elastomer is a mixture obtained by dispersing two kinds of carbon black, namely, Ketjen black and thermal black, in a blend of NBR and EPDM that are incompatible with each other and has a roll resistance of 10^{8.5} Ωcm and an Asker C hardness of 35 degrees.

The fixing unit 22 of the image-forming device is a fixing unit employed in a device, or DPC1616 manufactured by Fuji Xerox Co., Ltd. The fixing unit is placed, with the distance between a point where color forming information and non-color forming information are applied to a toner image and the fixing unit being 30 cm. The post-fixing irradiating unit 24 of the image-forming device is a high-brightness schaukasten (doctor's desk light) that can emit light having wavelengths the same as those of light emitted by the color forming information applying unit and that has an irradiation width of 5 mm.

The printing conditions in the image-forming device having the above configuration are as follows.
Linear velocity of photoreceptor 10 mm/second
Charging conditions A voltage of −400 V is applied to the Scorotron screen, and a direct current of −6 kV is applied to the wire. The surface electric potential of the photoreceptor charged under these conditions is −400 V.
Exposure conditions The photoreceptor is exposed to light at a light exposure serving as the logical sum of Y, M, C, and black-color image information, and the electric potential of the photoreceptor exposed is approximately −50 V.
Development bias An alternate voltage having Vpp of 1.2 kV (3 kHz) and rectangular waves is superimposed on a direct voltage of −330 V.
Contact conditions between developer and photoreceptor

The ratio of the peripheral speed of the development roll to that of the photoreceptor is 2.0, and the development gap is 0.5 mm, and the amount of the developer on the development roll is 400 g/m², and the amount of the toner that is made to adhere to a solid image on the photoreceptor is 5 g/m².
Transfer bias Direct voltage of +800 V
Fixing temperature The surface temperature of the fixing roll is set to 180° C.
Light source of color forming information applying unit
A Y-color irradiating unit 51Y emits light having a wavelength of 405 nm.
An M-color irradiating unit 51M emits light having a wavelength of 535 nm.
A C-color irradiating unit 51C emits light having a wavelength of 657 nm.
Illuminance of light irradiation unit of 130,000 lux.

Under the above conditions, an image data corresponding to an image that contains two picture regions 86A and 86B and character regions 87 shown in FIG. 7 is acquired in the image-forming device 10, and a routine shown in FIG. 5 is executed by the controller 46.

The color forming information applying unit 28 is controlled such that the Y-color irradiating unit 51Y, the M-color irradiating unit 51 M, and the C-color irradiating unit 51C irradiate regions of a toner image formed on the photoreceptor 11 which regions are to be glossed with light at light exposures of 100% in applying color forming information and non-color forming information to the toner image. As a result, no color can be formed in the regions.

When such a toner image is heated, two black picture regions 86A and 86B and character regions 87 are formed on a recording material 26, and non-colored glossing regions 84A and 84B are formed at regions touching and surrounding the respective picture regions 86A and 86B, as shown in FIG. 7.

The gloss of the recording material 26 is measured in accordance with JIS Z8741 by bringing a micro gloss meter manufactured by Gardner Co., Ltd. into close contact with the surface of the recording material 26 at an angle of incident of 75° at an angle of reflection of 75°. As a result, the gloss in the character region 87 is found to be 40, and the gloss in each of the picture regions 86A and 86B is found to be 60, and the gloss in each of the glossing regions 84A and 84B is found to be 50.

Thus, it is possible to selectively form a glossing region 84 in an image-forming device having a simple configuration without using a complicated device for glossing.

### EXAMPLE 2

An image is formed and evaluated in the same manner as in Example 1, except that the developer (1) is replaced with the developer (2). As a result, results similar to those in Example 1 are obtained.

Specifically, the gloss of the recording material 26 is measured in the same manner as in Example 1, and the gloss in the character region 87 is found to be 45 and the gloss in each of the picture regions 86A and 86B is found to be 65, and the gloss in each of the glossing regions 84A and 84B is found to be 50. Thus, it is possible to selectively form a glossing region 84 in an image-forming device having a simple configuration without using a complicated device for glossing.

### EXAMPLE 3

An image is formed and evaluated in the same manner as in Example 1, except that the developer (1) is replaced with the developer (3) including an optical color-forming toner.

The color forming information applying unit 28 is controlled such that the Y-color irradiating unit 51Y, the M-color irradiating unit 51M, and the C-color irradiating unit 51C do not irradiate regions of a toner image formed on the photoreceptor 11 which regions are to be glossed in applying color forming information and non-color forming information to the toner image. As a result, no color can be formed in the regions.

When such a toner image is heated, two black picture regions 86A and 86B and character regions 87 are formed on a recording material 26, and non-colored glossing regions 84A and 84B are formed at regions touching and surrounding the respective picture regions 86A and 86B, as shown in FIG. 7.

The gloss of the recording material 26 is measured in the same manner as in Example 1, and the gloss in the character region 87 is found to be 40and the gloss in each of the picture regions 86A and 86B is found to be 55, and the gloss in each of the glossing regions 84A and 84B is found to be 65.

Thus, it is possible to selectively form a glossing region 84 in an image-forming device having a simple configuration without using a complicated device for glossing.

What is claimed is:

1. An image-forming device comprising:
an image-holding member;
a charging unit that electrically charges the image-holding member;
an electrostatic latent image forming unit that forms an electrostatic latent image on the electrically charged image-holding member,
a toner image forming unit that forms a toner image on the image-holding member by adhering a toner on the electrostatic latent image, the toner being in a first state that can form a specific color when color forming information is applied, and the toner being in a second state that cannot form the specific color when non-color forming information is applied,
a glossing region selecting unit that selects a glossing region on a recording material that the toner image is to be fixed,
a color forming information applying unit that applies the non-color forming information to a region of the toner image that corresponds to the glossing region on the recording material, and applies the color forming information to a part of a region that does not correspond to the glossing region,
a transfer unit that transfers the toner image on the image-holding member to the recording material,
a fixing unit that fixes the toner image to the recording material,
a color forming unit that forms a color of the toner image on the recording material.

2. The image-forming device according to claim 1, further comprising:
an image data acquiring unit that acquires image data according to an image of an original,
a glossing-region data forming unit that forms data of the glossing region based on the selected glossing region,
a composite image data forming unit that integrates the image data and the glossing-region data to form a composite image data,
and the electrostatic latent image forming unit forming the electrostatic latent image by irradiating the image-holding member based on the composite image data.

3. The image-forming device according to claim 1, wherein the toner image includes a picture region, and the glossing-region selecting unit selects a region touching and surrounding the picture region as the glossing region.

4. The image-forming device according to claim 3, wherein the picture region is a graphic or a photograph.

5. The image-forming device according to claim 3, further comprising an image-type information acquiring unit that acquires image-type information indicating a type of image included in the toner image, and the glossing-region selecting unit selecting a touching and surrounding region of the region that corresponds to the image type of the acquired image-type information as the glossing-region.

6. The image-forming device according to claim 1, wherein the fixing unit is provided integrally with the color forming unit.

7. The image-forming device according to claim 1, further comprising a post-fixing irradiating unit that irradiates the toner image after the toner image is fixed on the recording material.

8. The image-forming device according to claim 1, wherein the image of an original has a plurality of specific colors and the toner can form the plurality of specific colors and the color forming unit irradiates the toner image with light having different wavelengths that corresponds to the specific colors of the image of an original and changes the toner into the first state or into the second state.

9. The image-forming device according to claim 8, wherein the toner forms no color and remains its inherent color or colorlessness in the region to be glossed.

10. The image-forming device according to claim 1, wherein the toner optically and irreversibly switches from the first state to the second state or from the second state to the first state.

11. The image-forming device according to claim 1, wherein the color forming unit irradiates the toner image transferred onto the recording material.

12. The image-forming device according to claim 1, wherein the transfer unit transfers the irradiated toner image onto a recording material.

13. The image-forming device according to claim 1, wherein the toner has a first component and a second component that are present separated from each other and form a color when reacted with each other and a photocurable composition containing any one of the first component and the second component, and, by applying the color forming information with light, the photocurable composition holds a cured or uncured state to control the reaction for color forming.

14. An image-forming device comprising:
an image-holding member;
a charging unit that electrically charges the image-holding member
an electrostatic latent image forming unit that forms an electrostatic latent image on the electrically charged image-holding member,
a toner image forming unit that forms a toner image on the image-holding member by adhering a toner on the electrostatic latent image, the toner being able to form a specific color when color forming information is applied, and the toner being able to form the color corresponding to a recording material that the toner image is to be fixed when non-color forming information is applied,
a glossing region selecting unit that selects a glossing region on the recording material,
a color forming information applying unit that applies the non-color forming information to a region of the toner image that corresponds to the glossing region on the recording material, and applies the color forming information to a part of a region that does not correspond to the glossing region,
a transfer unit that transfers the toner image on the image-holding member to the recording material,
a fixing unit that fixes the toner image to the recording material,
a color forming unit that forms a color of the toner image on the recording material.
